(19) United States
(12) Patent Application Publication
(10) Pub. No.: US 2018/0170005 A1
(43) Pub. Date: Jun. 21, 2018

(54) CURABLE COMPOSITION, PREPREG, METAL FOIL WITH COMPOSITION, METAL-CLAD LAMINATE AND WIRING BOARD

(71) Applicant: Panasonic Intellectual Property Management Co., Ltd., Osaka (JP)

(72) Inventors: HIROSUKE SAITO, Osaka (JP); HIROAKI FUJIWARA, Nara (JP)

(73) Assignee: Panasonic Intellectual Property Management Co., Ltd., Osaka (JP)

(21) Appl. No.: 15/580,272

(22) PCT Filed: Jun. 20, 2016
(86) PCT No.: PCT/JP2016/002943

§ 371 Date: Dec. 6, 2017

(30) Foreign Application Priority Data
Jun. 30, 2015 (JP) 2015-130674
Oct. 7, 2015 (JP) 2015-199038

(51) Int. Cl. B32B 15/06; C08F 2/44; B32B 27/30; C08K 5/5399; C08J 5/24; C08L 9/06; C08F 36/04; H05K 1/03

(52) U.S. Cl. CPC B32B 15/06; C08F 2/44; B32B 27/302; H05K 1/0373; C08J 5/24; C08L 9/06; C08F 36/04; C08K 5/5399

(57) ABSTRACT

A curable composition includes a radically polymerizable compound having a carbon-carbon unsaturated double bond in a molecule, and an insoluble phosphorus compound insoluble in the radically polymerizable compound. The insoluble phosphorus compound includes a phosphine oxide compound having two or more diphenylphosphine oxide groups in a molecule.

### TECHNICAL FIELD

The present invention relates to a curable composition, a prepreg, a composition-coated metal foil, a metal-clad laminate, and a wiring board.

### BACKGROUND ART

In recent years, along with an increase in quantity of information to be processed, rapidly developing in various electronic devices are mounting techniques such as high integration of a semiconductor device to be mounted, increasing density of wiring, and multilayering of wiring. Wiring boards such as a printed wiring board used in various electronic devices are demanded of not only high heat resistance but also reduction in loss during signal transmission to increase a rate of signal transmission. To fulfill these demands, it is considered to use a material that has a low dielectric constant and a low dissipation factor as a substrate material for producing an insulating layer of a wiring board.

An epoxy resin can be exemplified as a material that is widely used for, for example, a material that is demanded of heat resistance. The epoxy resin, however, generates a polar group such as a hydroxy group or an ester group after cured, so that production of the insulating layer made from the epoxy resin is less likely to realize an insulating layer having a low dielectric constant and a low dissipation factor, i.e., excellent dielectric properties. Therefore, as the substrate material, it is considered not to use a material, such as an epoxy resin, that newly generates a polar group after cured, but to use a composition that does not newly generate a polar group after cured and is cured by radical polymerization.

On the other hand, molding materials such as a substrate material are demanded of not only excellent dielectric properties and heat resistance but also excellent flame retardancy. Generally blended in many of curable compositions used as the molding materials such as a substrate material is a halogen-containing compound such as a halogen-based flame retardant (e.g., a bromine-based flame retardant) or a halogen-containing epoxy resin (e.g., a tetrabromobisphenol A-type epoxy resin).

However, a cured product of the curable composition containing such a halogen-containing compound also contains a halogen. Therefore, such a cured product may possibly generate a toxic substance such as a hydrogen halide when combusted. Accordingly, it has been pointed out that such a cured product may possibly give an adverse effect on a human body or a natural environment. Under such circumstances, the molding materials such as a substrate material are demanded of not containing a halogen, i.e. halogen-free.

As such a halogen-free curable composition, there can be exemplified a resin composition disclosed in PTL 1.

PTL 1 discloses a polyphenylene ether resin composition obtained by blending a polyphenylene ether resin having a predetermined terminal structure, a crosslinking agent, a phosphinate-based flame retardant, and a curing catalyst.

The resin composition disclosed in PTL 1 realizes the halogen-free by containing, as a flame retardant, a phosphorus-based flame retardant instead of the halogen-based flame retardant. PTL 1 describes that the resin composition gives a cured product that is excellent in heat resistance and flame retardancy and has excellent dielectric properties.

### CITATION LIST

### Patent Literature

PTL 1: Unexamined Japanese Patent Publication No. 2010-53178

### SUMMARY OF THE INVENTION

A substrate material for constituting a base material of a wiring board such as a printed wiring board relates to development of mounting techniques such as high integration of a semiconductor device, increasing density of wiring, and multilayering of wiring, and is therefore required of various characteristics. For example, the substrate material is subjected to an alkali treatment under high temperature and high concentration conditions during a desmear treatment or a repair treatment, so that the substrate sometimes comes to be whitened. In order to avoid such a defect, the substrate material is also demanded of high chemical resistance. For the reasons and the like described above, the substrate material is demanded of more excellent dielectric properties, heat resistance, and flame retardancy. On the other hand, the substrate material is also demanded of high adhesion strength between layers constituting an insulating layer and between a circuit and the insulating layer, and high resistance against a chemical in contact with the substrate materials in processing a wiring board. That is, a curable composition used as a molding material such as a substrate material is demanded of, even when containing a flame retardant, giving a cured product excellent in adhesion strength between cured products, adhesion strength to, for example, a metal foil provided on the cured product, and chemical resistance while the cured product maintaining excellent dielectric properties and heat resistance.

An object of the present invention is to provide a curable composition that gives a cured product excellent in dielectric properties, heat resistance, flame retardancy, adhesion strength, and chemical resistance. Another object of the present invention is to provide a prepreg, a composition-coated metal foil, a metal-clad laminate, and a wiring board that can be obtained with use of the curable composition.

A curable composition according to one aspect of the present invention includes a radically polymerizable compound having a carbon-carbon unsaturated double bond in a molecule, and an insoluble phosphorus compound insoluble in the radically polymerizable compound. The insoluble phosphorus compound includes a phosphine oxide compound having two or more diphenylphosphine oxide groups in a molecule.

According to the present invention, there can be provided a curable composition that gives a cured product excellent in dielectric properties, heat resistance, flame retardancy, adhesion strength, and chemical resistance. According to the present invention, there can also be provided a prepreg, a composition-coated metal foil, a metal-clad laminate, and a wiring board that can be obtained with use of the curable composition.

### BRIEF DESCRIPTION OF DRAWINGS

FIG. 1 is a schematic sectional view illustrating a prepreg according to an exemplary embodiment of the present invention.

FIG. 2 is a schematic sectional view illustrating a composition-coated metal foil according to the exemplary embodiment of the present invention.

FIG. 3 is a schematic sectional view illustrating a metal-clad laminate according to the exemplary embodiment of the present invention.

FIG. 4 is a schematic sectional view illustrating a wiring board according to the exemplary embodiment of the present invention.

### DESCRIPTION OF EMBODIMENT

In order to enhance the flame retardancy of a cured product of a curable composition, a content of a flame retardant in the curable composition is considered to be increased. According to study of the present inventors and the like, however, only an increase in content of the flame retardant sometimes decreases the dielectric properties and the heat resistance of the cured product.

For example, as a flame retardant soluble in a radically polymerizable compound that is cured through radical polymerization, there can be exemplified a phosphoric acid ester compound and a phosphazene compound. When the flame retardancy is attempted to be secured with use of such a flame retardant, the dielectric properties, a glass transition temperature, and the heat resistance of the cured product is likely to decrease.

As a flame retardant insoluble in the radically polymerizable compound, there can be exemplified a phosphinate compound and a polyphosphate compound. When the flame retardancy is attempted to be secured with use of, instead of the flame retardant soluble in the radically polymerizable compound, these flame retardants insoluble in the radically polymerizable compound, the dielectric properties, reliability, and the chemical resistance of the cured product is likely to decrease.

In order to secure the flame retardancy, it is also considered to use in combination the flame retardant soluble in the radically polymerizable compound and the flame retardant insoluble in the radically polymerizable compound. Such combination use, however, cannot sometimes sufficiently suppress generation of a defect caused by the flame retardant insoluble in the radically polymerizable compound. Particularly, the phosphinate compound and the polyphosphate compound are salts and are likely to cause a decrease in chemical resistance due to a nature of the compounds, and the generation of this defect cannot sometimes sufficiently be suppressed. For the reasons described above, the curable composition is demanded of giving a cured product more excellent in dielectric properties, heat resistance, flame retardancy, adhesion strength between cured products, adhesion strength to, for example, a metal, and chemical resistance.

Hereinafter, an exemplary embodiment according to the present invention is described. The present invention, however, is not limited to this exemplary embodiment.

A curable composition according to an exemplary embodiment of the present invention includes a radically polymerizable compound having a carbon-carbon unsaturated double bond in a molecule, and an insoluble phosphorus compound insoluble in the radically polymerizable compound. The term insoluble in this case refers to a state in which the object (insoluble phosphorus compound) is insoluble in the radically polymerizable compound and dispersed into island shapes in a mixture. The insoluble phosphorus compound includes a phosphine oxide compound having two or more diphenylphosphine oxide groups in a molecule.

Such a curable composition can give, when cured, a cured product excellent in dielectric properties, heat resistance, flame retardancy, adhesion strength between cured products, adhesion strength to, for example, a metal, and chemical resistance. That is, such a curable composition can give a cured product excellent in dielectric properties, heat resistance, flame retardancy, adhesion strength between cured products, adhesion strength to, for example, a metal, and chemical resistance.

This is considered to be due to following reasons.

The curable composition contains, as the flame retardant, a phosphine oxide compound instead of a soluble phosphorus compound soluble in the radically polymerizable compound. It is considered that since the phosphine oxide compound is insoluble in the radically polymerizable compound, a defect can be suppressed that is caused by adding the soluble phosphorus compound in large amounts. The phosphine oxide compound that is not a salt is considered to be also capable of suppressing a decrease in adhesion strength between cured products, adhesion strength to, for example, a metal, and chemical resistance. Further, it is considered that even in an attempt to secure the flame retardancy by adding such a flame retardant, it is possible to sufficiently prevent polymerization by the radically polymerizable compound from being inhibited. Therefore, it is considered that the radically polymerizable compound can suitably be polymerized and does not newly generate a polar group such as a hydroxy group in a cured product obtained after curing through the polymerization, so that a cured product can be obtained that is excellent in dielectric properties and heat resistance.

As described above, the curable composition is considered to suitably give a cured product excellent in dielectric properties, heat resistance, flame retardancy, adhesion strength, and chemical resistance. An insulating layer provided in a wiring board can be formed with use of such a curable composition to give an excellent wiring board.

The curable composition is a composition that is cured through radical polymerization. The composition that is cured through radical polymerization also has an advantage that a curing period is shorter than a curing period of a thermosetting resin such as an epoxy resin composition. Such a composition also has an advantage of being more excellent in impregnation properties into a fibrous base material such as glass cloth than the thermosetting resin.

The insoluble phosphorus compound used in the present exemplary embodiment serves as the flame retardant. The insoluble phosphorus compound is not particularly limited as long as the insoluble phosphorus compound includes the phosphine oxide compound having two or more diphenylphosphine oxide groups in the molecule. The phosphine oxide compound is preferred to have two diphenylphosphine oxide groups in the molecule. The diphenylphosphine oxide group is represented by a formula (6). This phosphine oxide compound having two or more diphenylphosphine oxide groups in the molecule may be a phosphine oxide compound having, in the molecule, two or more methylene diphenylphosphine oxide groups in which a methylene group is bonded to a phosphorus atom of a diphenylphosphine oxide group. This methylene diphenylphosphine oxide group is represented by a formula (7). The phosphine oxide compound having two or more methylene diphenylphosphine oxide groups as described above in the molecule has two or more diphenylphosphine oxide groups in the molecule.

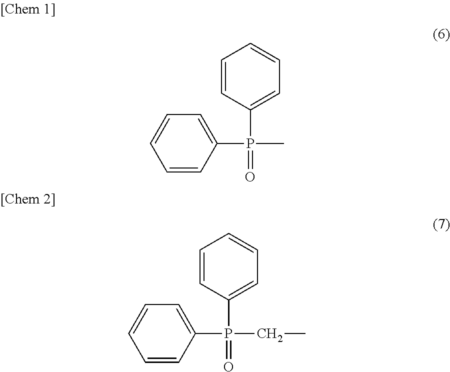 [SMILES: CP(=O)(c1ccccc1)c1ccccc1 ; CCP(=O)(c1ccccc1)c1ccccc1]

The phosphine oxide compound has a melting point of preferably 280° C. or more, more preferably 310° C. or more. The curable composition containing the phosphine oxide compound having a melting point in these ranges gives a cured product having a lower dissipation factor. This phenomenon is considered to be because crystallinity of the curable composition is increased to suppress molecular motion. The curable composition that contains the phosphine oxide compound having a too low melting point is unlikely to be capable of sufficiently exhibiting an effect of increasing the dissipation factor of a cured product. Although the phosphine oxide compound preferably has as high a melting point as possible, the maximum melting point of the phosphine oxide compound is about 450° C. from the viewpoint of decomposition temperature of an organic substance. For the reasons described above, the phosphine oxide compound has a melting point ranging preferably from 280° C. to 450° C., inclusive, more preferably from 310° C. to 450° C., inclusive. The melting point can be measured with use of, for example, a simultaneous thermogravimetric/differential thermal analyzer (TG/DTA). Specifically, the melting point can be measured from an exothermic peak in DTA obtained by measuring, with use of the TG/DTA, the phosphine oxide compound in nitrogen at a temperature rising rate of 10° C./min from room temperature to 500° C.

Since the phosphine oxide compound has two or more diphenylphosphine oxide groups, the phosphine oxide compound is preferred to have a linking group that connects these groups in the molecule. The linking group is not particularly limited, and the linking group preferably include, for example, a phenylene group, a xylylene group, a biphenylene group, a naphthylene group, a methylene group, and an ethylene group, and more preferably a phenylene group, a xylylene group, a biphenylene group, and a naphthylene group that are likely to give the phosphine oxide compound having a high melting point.

More specifically, the phosphine oxide compound is preferably a compound represented by any one of formulae (1-1) to (1-4) and formulae (2) to (5), more preferably a compound represented by any one of the formulae (1-1) to (1-4).

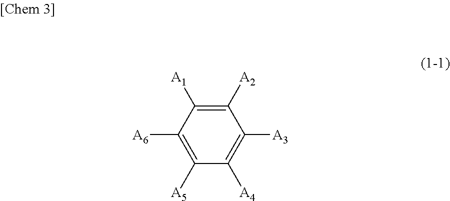

In the formula (1-1), two of A₁ to A₆ represent a diphenylphosphine oxide group, and remaining four of A₁ to A₆ represent a hydrogen atom, a methyl group, or a methoxy group.

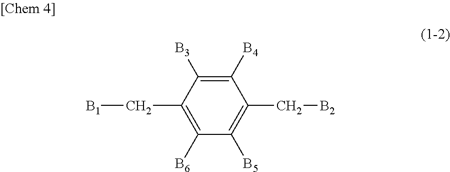

In the formula (1-2), B₁ and B₂ represent a diphenylphosphine oxide group, and B₃ to B₆ represent a hydrogen atom, a methyl group, or a methoxy group.

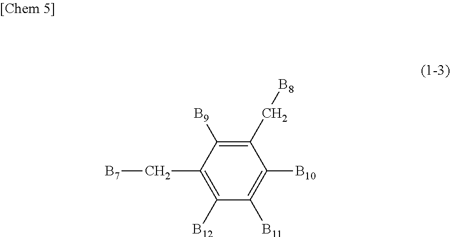

In the formula (1-3), B₇ and B₈ represent a diphenylphosphine oxide group, and B₉ to B₁₂ represent a hydrogen atom, a methyl group, or a methoxy group.

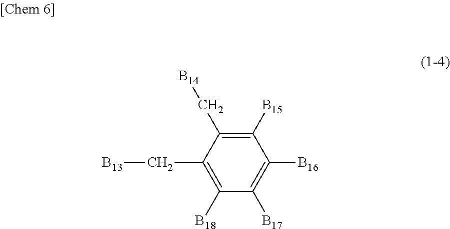

In the formula (1-4), B₁₃ and B₁₄ represent a diphenylphosphine oxide group, and B₁₅ to B₁₈ represent a hydrogen atom, a methyl group, or a methoxy group.

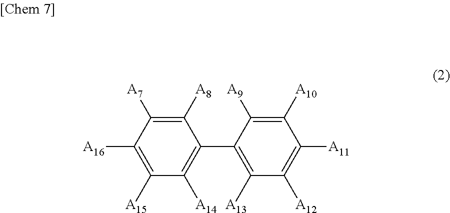

In the formula (2), two of A₇ to A₁₆ represent a diphenylphosphine oxide group. Remaining eight of A₇ to A₁₆ represent a hydrogen atom, a methyl group, or a methoxy group.

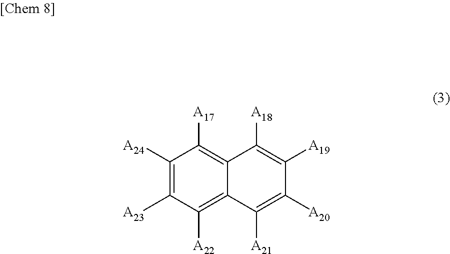

In the formula (3), two of A₁₇ to A₂₄ represent a diphenylphosphine oxide group. Remaining six of A₁₇ to A₂₄ represent a hydrogen atom, a methyl group, or a methoxy group.

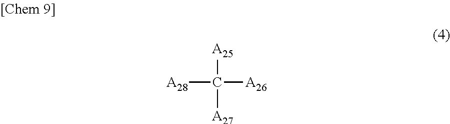

In the formula (4), two of A₂₅ to A₂₈ represent a diphenylphosphine oxide group. Remaining two of A₂₅ to A₂₈ represent a hydrogen atom, a methyl group, or a methoxy group.

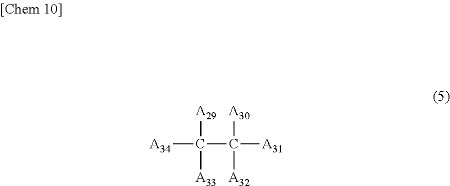

In the formula (5), two of A₂₉ to A₃₄ represent a diphenylphosphine oxide group. Remaining four of A₂₉ to A₃₄ represent a hydrogen atom, a methyl group, or a methoxy group.

A group including a diphenylphosphine oxide group may be, for example, the diphenylphosphine oxide group or may be a methylene diphenylphosphine oxide group.

More specific examples of the phosphine oxide compound include xylylene bisdiphenylphosphine oxides such as a compound (para-xylylene bisdiphenylphosphine oxide) represented by a formula (13), phenylene bisdiphenylphosphine oxides such as a compound (para-phenylene bisdiphenylphosphine oxide) represented by a formula (14), an ethylene bisdiphenylphosphine oxide represented by a formula (15), a compound represented by a formula (16), a biphenylene bisdiphenylphosphine oxide, and a naphthylene bisdiphenylphosphine oxide. Among these examples, more preferred are xylylene bisdiphenylphosphine oxide and phenylene bisdiphenylphosphine oxide, and further preferred are xylylene bisdiphenylphosphine oxide and phenylene bisdiphenylphosphine oxide that each have the two diphenylphosphine oxide groups at bonding positions of 1,4-positions, 1,2-positions, 1,1′-positions, 1,5-positions, or 2,6-positions.

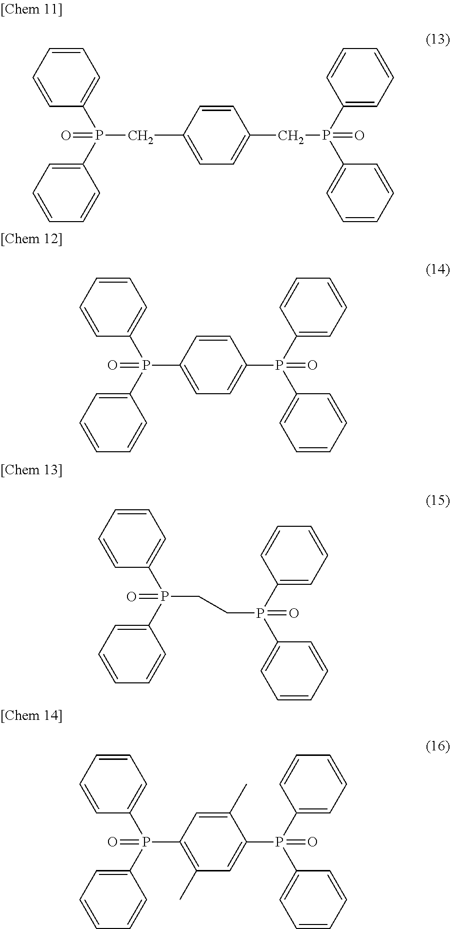 [SMILES: O=P(Cc1ccc(CP(=O)(c2ccccc2)c2ccccc2)cc1)(c1ccccc1)c1ccccc1 ; O=P(c1ccccc1)(c1ccccc1)c1ccc(P(=O)(c2ccccc2)c2ccccc2)cc1 ; O=P(CCP(=O)(c1ccccc1)c1ccccc1)(c1ccccc1)c1ccccc1 ; Cc1cc(P(=O)(c2ccccc2)c2ccccc2)c(C)cc1P(=O)(c1ccccc1)c1ccccc1]

One phosphine oxide compound may be used alone, or two or more phosphine oxide compounds may be used in combination.

The curable composition may contain only the phosphine oxide compound as the insoluble phosphorus compound or may also contain another insoluble phosphorus compound without remarkably impairing the effects of the present invention. The other insoluble phosphorus compound is preferred to be a phosphine oxide compound. The other insoluble phosphorus compound is not particularly limited as long as the other insoluble phosphorus compound acts as the flame retardant and is an insoluble phosphorus compound insoluble in the radically polymerizable compound. As the insoluble phosphorus compound, there can be exemplified a phosphinate compound, a polyphosphate compound, and a phosphonium salt compound. Examples of the phosphinate compound include aluminum thalkylphosphinate, aluminum trisdiethylphosphinate, aluminum trismethylethylphosphinate, aluminum trisdiphenylphosphinate, zinc bisdiethylphosphinate, zinc bismethylethylphosphinate, zinc bisdiphenylphosphinate, titanyl bisdiethylphosphinate, titanyl bismethylethylphosphinate, and titanyl bisdiphenylphosphinate. Examples of the polyphosphate compound include melamine polyphosphate, melam polyphosphate, and melem polyphosphate. Examples of the phosphonium salt compound include tetraphenylphosphonium tetraphenylborate and tetraphenylphosphonium bromide. As the other insoluble phosphorus compound, one insoluble phosphorus compound may be used alone, or two or more insoluble phosphorus compounds may be used in combination.

The curable composition according to the present exemplary embodiment is preferred to contain a soluble phosphorus compound soluble in the radically polymerizable compound together with the insoluble phosphorus compound such as the phosphine oxide compound, in terms of enhancing the flame retardancy of a cured product obtained. This is because using, as the flame retardant, the soluble phosphorus compound and the insoluble phosphorus compound in combination is considered to be capable of giving a cured product obtained higher in flame retardancy than when either one of the soluble phosphorus compound and the insoluble phosphorus compound is used. Since the curable composition contains the phosphine oxide compound as the insoluble phosphorus compound, the curable composition is considered to give a cured product more excellent in flame retardancy while the cured product maintaining excellent heat resistance, even when the curable composition containing the soluble phosphorus compound to decrease the heat resistance such as a little decrease in glass transition temperature. Therefore, the curable composition is considered to be higher in flame retardancy while maintaining excellent heat resistance. The term soluble in this case refers to a state in which the object (soluble phosphorus compound) is finely dispersed, for example, at a molecular level, in the radically polymerizable compound.

As the soluble phosphorus compound, there can be exemplified a phosphoric acid ester compound, a phosphazene compound, a phosphorous acid ester compound, and a phosphine compound. Examples of the phosphazene compound include a cyclic or chain phosphazene compound. The cyclic phosphazene compound is also referred to as a cyclophosphazene, is a compound having in a molecule a double bond formed of phosphorus and nitrogen as constituent elements, and has a cyclic structure. Examples of the phosphoric acid ester compound include triphenyl phosphate, tricresyl phosphate, xylenyldiphenyl phosphate, cresyldiphenyl phosphate, 1,3-phenylenebis(di2,6-xylenyl phosphate), 9,10-dihydro-9-oxa-10-phosphaphenanthrene-10-oxide (DOPO), condensed phosphoric acid ester compounds such as an aromatic condensed phosphoric acid ester compound, and a cyclic phosphoric acid ester compound. Examples of the phosphorous acid ester compound include trimethyl phosphite and triethyl phosphite. Examples of the phosphine compound include tris-(4-methoxyphenyl)phosphine and triphenylphosphine. One soluble phosphorus compound may be used alone, or two or more soluble phosphorus compounds may be used in combination.

A content proportion by mass of the insoluble phosphorus compound to a total of the insoluble phosphorus compound and the soluble phosphorus compound ranges preferably from 20% to 80%, inclusive, more preferably from 50% to 80%, inclusive. The curable composition containing too little of the insoluble phosphorus compound, i.e., having a small content of the phosphine oxide compound is unlikely to exhibit the effects of the present exemplary embodiment. The curable composition containing too little of the soluble phosphorus compound is unlikely to exhibit the effect brought about by combination use of the soluble phosphorus compound and the insoluble phosphorus compound, so that the flame retardancy is likely to decrease. Therefore, with the content proportion in the ranges described above, the effect is considered to be more exhibited that is brought about by using, as the flame retardant, the soluble phosphorus compound and the insoluble phosphorus compound in combination. Accordingly, the curable composition can be adjusted that can give a cured product more excellent in heat resistance and flame retardancy.

The curable composition has a phosphorus atom content ranging preferably from 1.8% by mass to 5.2% by mass, inclusive, more preferably from 1.8% by mass to 5.0% by mass, inclusive, further preferably from 1.8% by mass to 4.8% by mass, inclusive, relative to a whole organic component. A content of the flame retardant is preferred to be such a content that gives the phosphorus atom content in the ranges described above in the curable composition. The content of the flame retardant in these ranges affords the curable composition that can give a cured product more excellent in flame retardancy while the cured product maintaining, for example, excellent dielectric properties and heat resistance. This is considered to be because such a curable composition can sufficiently enhance the flame retardancy while sufficiently suppressing a decrease in, for example, dielectric properties and heat resistance of a cured product that is caused by containing the flame retardant. The term organic component includes organic components of, for example, the radically polymerizable compound, the insoluble phosphorus compound, and the soluble phosphorus compound. When another organic component is additionally added, the organic component also includes the additionally added organic component.

The curable composition according to the present exemplary embodiment may contain the flame retardant consisting of the soluble phosphorus compound and the insoluble phosphorus compound or may also contain a flame retardant other than the two compounds. The curable composition according to the present exemplary embodiment may contain, as the flame retardant, a flame retardant other than the soluble phosphorus compound and the insoluble phosphorus compound. The curable composition, however, is preferred to contain no halogen-based flame retardant from the viewpoint of halogen-free.

The radically polymerizable compound used in the present exemplary embodiment is not particularly limited as long as the radically polymerizable compound is a compound having an unsaturated double bond in a molecule, i.e., a compound having a radically polymerizable unsaturated group in a molecule. As the radically polymerizable compound, there can be exemplified a polymer of a conjugated diene, such as polybutadiene; a copolymer including a conjugated diene; a vinyl ester resin that is, for example, a reaction product of an unsaturated fatty acid such as acrylic acid or methacrylic acid, with an epoxy resin; an unsaturated polyester resin; and a modified polyphenylene ether compound terminally modified with a substituent having a carbon-carbon unsaturated double bond. Examples of the copolymer including a conjugated diene include a copolymer of a conjugated diene with a vinyl aromatic compound, such as a butadiene-styrene copolymer; an acrylonitrile-butadiene copolymer; and an acrylonitrile-butadiene-styrene copolymer. Among these examples, the radically polymerizable compound is preferably polybutadiene, a butadiene-styrene copolymer, and a modified polyphenylene ether compound, more preferably a modified polyphenylene ether compound. Use of the modified polyphenylene ether compound as the radically polymerizable compound enables adjustment of the curable composition that can give a cured product excellent in dielectric properties, high in glass transition temperature Tg, and more excellent in heat resistance. As the radically polymerizable compound, the compounds described above may be used alone, or two or more of the compounds may be used in combination.

The modified polyphenylene ether compound is not particularly limited as long as the modified polyphenylene ether compound is a polyphenylene ether terminally modified with a substituent having a carbon-carbon unsaturated double bond.

The substituent having a carbon-carbon unsaturated double bond is not particularly limited. As the substituent, there can be exemplified a substituent represented by a formula (8).

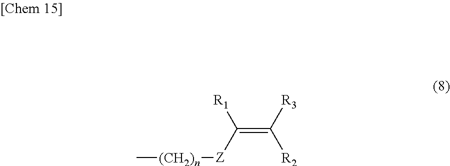

In the formula (8), n represents an integer of 0 to 10. Z represents an arylene group. R₁ to R₃ are each independent. That is, R₁ to R₃ may each be the same group or different groups. R₁ to R₃ represent a hydrogen atom or an alkyl group.

In the formula (8), when n is 0, Z is directly bonded to a terminal of the polyphenylene ether.

This arylene group is not particularly limited. Specific examples of the arylene group include a monocyclic aromatic group, such as a phenylene group, and a polycyclic aromatic group that has, instead of a monocyclic aromatic ring, a polycyclic aromatic ring such as a naphthalene ring. This arylene group also includes a derivative in which a hydrogen atom bonded to an aromatic ring is substituted with a functional group such as an alkenyl group, an alkynyl group, a formyl group, an alkylcarbonyl group, an alkenylcarbonyl group, or an alkynylcarbonyl group. The alkyl group is not particularly limited, and is preferably an alkyl group having 1 to 18 carbon atoms, more preferably an alkyl group having 1 to 10 carbon atoms, for example. Specific examples of such an alkyl group include a methyl group, an ethyl group, a propyl group, a hexyl group, and a decyl group.

More specific examples of the substituent having a carbon-carbon unsaturated double bond include a vinylbenzyl group (ethenylbenzyl group) such as a p-ethenylbenzyl group or an m-ethenylbenzyl group, a vinylphenyl group, an acrylate group, and a methacrylate group. The substituent having a carbon-carbon unsaturated double bond is preferred to be a vinylbenzyl group, a vinylphenyl group, and a methacrylate group. The compound having an allyl group as the substituent is likely to be low in reactivity. The compound having an acrylate group as the substituent is likely to be too high in reactivity.

Specific preferable examples of the substituent represented by the formula (8) include a functional group including a vinylbenzyl group. Specifically, there can be exemplified at least one substituent selected from formulae (9) and (10).

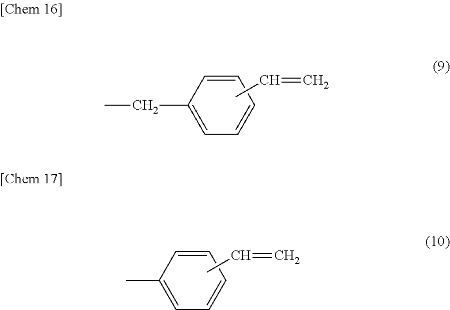

As another substituent having a carbon-carbon unsaturated double bond that terminally modifies the modified polyphenylene ether compound, there can be exemplified a (meth)acrylate group, which is represented by, for example, a formula (11).

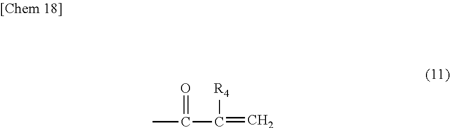

In the formula (11), R₄ represents a hydrogen atom or an alkyl group. The alkyl group is not particularly limited, and is preferably an alkyl group having 1 to 18 carbon atoms, inclusive, more preferably an alkyl group having 1 to 10 carbon atoms, inclusive, for example. Specific examples of such an alkyl group include a methyl group, an ethyl group, a propyl group, a hexyl group, and a decyl group.

The modified polyphenylene ether compound has a polyphenylene ether chain in a molecule and is preferred to have, in the molecule, a repeating unit represented by, for example, a formula (12).

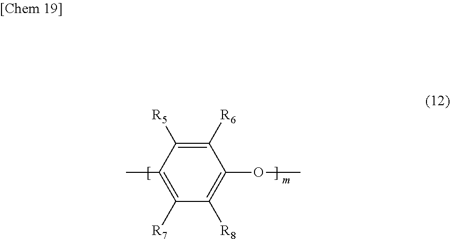

In the formula (12), m represents 1 to 50. R₅ to R₈ are each independent. That is, R₅ to R₈ may each be the same group or different groups. R₅ to R₈ represent a hydrogen atom, an alkyl group, an alkenyl group, an alkynyl group, a formyl group, an alkylcarbonyl group, an alkenylcarbonyl group, or an alkynylcarbonyl group. Among these atom and groups, a hydrogen atom and an alkyl group are preferable.

As R₅ to R₈, the exemplified functional groups are specifically as follows.

The alkyl group is not particularly limited, and is preferably an alkyl group having 1 to 18 carbon atoms, inclusive, more preferably an alkyl group having 1 to 10 carbon atoms, inclusive, for example. Specific examples of such an alkyl group include a methyl group, an ethyl group, a propyl group, a hexyl group, and a decyl group.

The alkenyl group is not particularly limited, and is preferably an alkenyl group having 2 to 18 carbon atoms, inclusive, more preferably an alkenyl group having 2 to 10 carbon atoms, inclusive, for example. Specific examples of such an alkenyl group include a vinyl group, an allyl group, and 3-butenyl group

The alkynyl group is not particularly limited, and is preferably an alkynyl group having 2 to 18 carbon atoms, inclusive, more preferably an alkynyl group having 2 or more and 10 or more carbon atoms, for example. Specific examples of such an alkynyl group include an ethynyl group and a prop-2-yn-1-yl group (propargyl group).

The alkylcarbonyl group is not particularly limited as long as the alkylcarbonyl group is a carbonyl group substituted with an alkyl group, and is preferably an alkylcarbonyl group having 2 to 18 carbon atoms, inclusive, more preferably an alkylcarbonyl group having 2 to 10 carbon atoms, inclusive, for example. Specific examples of such an alkylcarbonyl group include an acetyl group, a propionyl group, a butyryl group, an isobutyryl group, a pivaloyl group, a hexanoyl group, an octanoyl group, and a cyclohexylcarbonyl group.

The alkenylcarbonyl group is not particularly limited as long as the alkenylcarbonyl group is a carbonyl group substituted with an alkenyl group, and is preferably an alkenylcarbonyl group having 3 to 18 carbon atoms, inclusive, more preferably an alkenylcarbonyl group having 3 to 10 carbon atoms, inclusive, for example. Specific examples of such an alkenylcarbonyl group include an acryloyl group, a methacryloyl group, and a crotonoyl group.

The alkynylcarbonyl group is not particularly limited as long as the alkynylcarbonyl group is a carbonyl group substituted with an alkynyl group, and is preferably an alkynylcarbonyl group having 3 to 18 carbon atoms, inclusive, more preferably an alkynylcarbonyl group having 3 to 10 carbon atoms, inclusive, for example. Specific examples of such an alkynylcarbonyl group include a propioloyl group.

The modified polyphenylene ether compound is not particularly limited in terms of weight average molecular weight (Mw). Specifically, the weight average molecular weight of the modified polyphenylene ether compound ranges preferably from 500 to 5000, inclusive, more preferably from 500 to 2000, inclusive, further preferably from 1000 to 2000, inclusive. Here, any value is acceptable as the weight average molecular weight as long as the value is measured by a general molecular weight measuring method, and specifically exemplified is a value obtained by measuring the modified polyphenylene ether with use of gel permeation chromatography (GPC). When the modified polyphenylene ether compound has, in the molecule, a repeating unit represented by the formula (12), m is preferred to be such a value that gives a weight average molecular weight of the modified polyphenylene ether compound in such ranges. Specifically, m is preferred to be 1 to 50.

The modified polyphenylene ether compound having a weight average molecular weight in such ranges has excellent dielectric properties of the polyphenylene ether, and not only gives a cured product more excellent in heat resistance but also is excellent in moldability. This is considered to be due to following reasons. A normal polyphenylene ether having a weight average molecular weight in such ranges is likely to give a cured product having low heat resistance, which is attributed to a relatively low molecular weight of the polyphenylene ether. In contrast, it is considered that the modified polyphenylene ether compound gives a cured product having sufficiently high heat resistance, which is attributed to the unsaturated double bond at a terminal of the modified polyphenylene ether compound. The modified polyphenylene ether compound having a weight average molecular weight in such ranges, that is, having a relatively low molecular weight is considered to be also excellent in moldability. Therefore, such a modified polyphenylene ether compound is considered to not only give a cured product more excellent in heat resistance but also be excellent in moldability. On the other hand, the modified polyphenylene ether compound having a too low weight average molecular weight decreases the glass transition temperature, so that the heat resistance of a cured product is likely to decrease. Further, the modified polyphenylene ether compound having a too low weight average molecular weight comes to have a too short polyphenylene ether moiety to be unlikely to maintain excellent dielectric properties of the polyphenylene ether. The modified polyphenylene ether compound having a too high weight average molecular weight is likely to decrease solubility in a solvent or decrease preservation stability. Further, the modified polyphenylene ether compound having a too high weight average molecular weight becomes high in viscosity, so that the moldability is likely to decrease.

In the modified polyphenylene ether compound, an average number of substituents at a molecular terminal (number of terminal functional groups) per one molecule of the modified polyphenylene ether compound is not particularly limited. Specifically, the number of terminal functional groups ranges preferably from 1 to 5, inclusive, more preferably from 1 to 3, inclusive, further preferably from 1.5 to 3, inclusive. The modified polyphenylene ether compound having too few terminal functional groups comes to have too few moieties that contribute to radical polymerization, so that the heat resistance of a cured product is likely to be insufficient. The modified polyphenylene ether compound having too many terminal functional groups becomes too high in reactivity, so that the viscosity is likely to be excessively increased or an unreacted unsaturated double bond is likely to remain after curing. These phenomena may possibly deteriorate preserving properties and fluidity, cause change in color, or decrease the dielectric properties of a cured product, for example. That is, use of such a modified polyphenylene ether compound causes, due to lack of fluidity or the like, for example, generation of imperfect molding such as generation of a void during multilayer molding, possibly making it difficult to give a wiring board high in reliability.

The number of terminal functional groups of the modified polyphenylene ether compound is, for example, a value representing an average value of the substituents per one molecule in a whole modified polyphenylene ether compound present in 1 mol of the modified polyphenylene ether compound. This number of terminal function groups can be determined by, for example, measuring a number of hydroxy groups remaining in the modified polyphenylene ether compound obtained and calculating a decrease from a number of hydroxy groups in an unmodified polyphenylene ether. The decrease in the number of hydroxy groups from the unmodified polyphenylene ether is the number of terminal functional groups. The number of hydroxy groups remaining in the modified polyphenylene ether compound can be determined by adding a quaternary ammonium salt that is associated with a hydroxy group (tetraethylammonium hydroxide) to a solution of the modified polyphenylene ether compound and subjecting the mixed solution to UV (Ultra Violet) absorbance measurement.

The modified polyphenylene ether compound used in the present exemplary embodiment is not particularly limited in terms of intrinsic viscosity. Specifically, the intrinsic viscosity should range at least from 0.03 dl/g to 0.12 dl/g, inclusive, and ranges preferably from 0.04 dl/g to 0.11 dl/g, inclusive, further preferably from 0.06 dl/g to 0.095 dl/g, inclusive. The modified polyphenylene ether compound having a too low intrinsic viscosity is likely to be low in molecular weight, so that it is likely to be difficult to obtain low dielectric properties such as a low dielectric constant and a low dissipation factor. The modified polyphenylene ether compound having a too high intrinsic viscosity is high in viscosity not to obtain sufficient fluidity, so that the moldability for a cured product is likely to decrease. Therefore, the modified polyphenylene ether compound having an intrinsic viscosity in the ranges described above can realize a cured product excellent in heat resistance and moldability.

The intrinsic viscosity referred to herein is a value of intrinsic viscosity measured in methylene chloride at 25° C., and more specifically, for example, a value obtained by measuring a 0.18 g/45 ml (liquid temperature 25° C.) with a viscometer. As the viscometer, there can be exemplified AVS500 Visco System manufactured by SCHOTT Instruments GmbH.

A method for synthesizing the modified polyphenylene ether compound used in the present exemplary embodiment is not particularly limited as long as the method can synthesize the modified polyphenylene ether compound terminally modified with the substituent having a carbon-carbon unsaturated double bond. Specific examples of the method include a method of reacting the polyphenylene ether with a compound in which the substituent having a carbon-carbon unsaturated double bond is bonded to a halogen atom.

Examples of the compound in which the substituent having a carbon-carbon unsaturated double bond is bonded to a halogen atom include p-chloromethylstyrene and m-chloromethylstyrene.

The polyphenylene ether as a raw material is not particularly limited as long as the polyphenylene ether can give through synthesis a predetermined modified polyphenylene ether compound in the end. Examples of the polyphenylene ether include a polyphenylene ether formed of 2,6-dimethylphenol and at least one of bifunctional phenol and trifunctional phenol, and one containing as a main component a polyphenylene ether such as poly(2,6-dimethyl-1,4-phenylene oxide). The bifunctional phenol refers to a phenolic compound having two phenolic hydroxy groups in a molecule, and examples of the bifunctional phenol include tetramethyl bisphenol A. The trifunctional phenol refers to a phenolic compound having three phenolic hydroxy groups in a molecule.

Specifically, the method for synthesizing the modified polyphenylene ether compound is dissolving in a solvent the polyphenylene ether and the compound in which the substituent having a carbon-carbon unsaturated double bond is bonded to a halogen atom and stirring the resulting mixed solution. This procedure allows the polyphenylene ether to react with the compound in which the substituent having a carbon-carbon unsaturated double bond is bonded to a halogen atom, to give the modified polyphenylene ether compound.

The curable composition according to the present exemplary embodiment may also contain, as the radically polymerizable compound, a crosslinking agent having two or more carbon-carbon unsaturated double bonds in a molecule. The curable composition containing the crosslinking agent gives a cured product having an increased glass transition temperature, enhancing the heat resistance of the cured product. This phenomenon is considered to be because a crosslinked structure of the cured product becomes stronger. The curable composition is preferred to contain the crosslinking agent when containing the modified polyphenylene ether compound. That is, the curable composition is preferred to contain, as the radically polymerizable compound, the modified polyphenylene ether compound and the crosslinking agent.

The crosslinking agent is not particularly limited as long as the crosslinking agent has two or more carbon-carbon unsaturated double bonds in the molecule. That is, any crosslinking agent is acceptable as long as the crosslinking agent reacts with the radically polymerizable compound such as the modified polyphenylene ether compound to form a crosslink and thus cure the curable composition.

A molecular weight of the crosslinking agent ranges preferably from 100 to 5000, inclusive, more preferably from 100 to 4000, inclusive, further preferably from 100 to 3000, inclusive. The crosslinking agent having a too low molecular weight may possibly be likely to volatilize from a blended component system of the curable composition. The crosslinking agent having a too high molecular weight may possibly excessively increase the viscosity of the curable composition or melt viscosity during heat molding. Therefore, the crosslinking agent having a molecular weight in such ranges can give the curable composition that provides a cured product more excellent in heat resistance. This is considered to be because a crosslink can suitably be formed due to a reaction of the crosslinking agent with the radically polymerizable compound such as the modified polyphenylene ether compound. The molecular weight referred to herein is a weight average molecular weight when the crosslinking agent is a polymer or an oligomer. As the weight average molecular weight, any value is acceptable as long as the value is measured by a general molecular weight measuring method, and specifically exemplified is a value obtained by measuring the crosslinking agent with use of gel permeation chromatography (GPC).

In the crosslinking agent, an average number of carbon-carbon unsaturated double bonds per one molecule of the crosslinking agent (number of terminal double bonds) is different according to the molecular weight of the crosslinking agent. The number of terminal double bonds ranges preferably from 1 to 20, more preferably from 2 to 18, for example. The crosslinking agent having too few terminal double bonds is likely to give a cured product insufficient in heat resistance. The crosslinking agent having too many terminal double bonds becomes too high in reactivity, possibly deteriorating the preserving properties of the curable composition or the fluidity of the curable composition, for example.

In more consideration of the molecular weight of the crosslinking agent, the number of terminal double bonds of the crosslinking agent preferably ranges from 1 to 4 when the molecular weight of the cross linking agent is less than 500 (e.g., 100 or more and less than 500). The number of terminal double bonds of the crosslinking agent preferably ranges from 3 to 20 when the molecular weight of the cross linking agent is 500 or more (e.g., 500 to 5000, inclusive). In either case, when the number of terminal double bonds is lower than the lower limit value of the ranges described above, the reactivity of the crosslinking agent decreases to lower crosslink density in a cured product of the curable composition, so that the heat resistance and the Tg may not possibly be sufficiently improved. On the other hand, when the number of terminal double bonds is greater than the upper limit value of the ranges described above, the curable composition may possible be liable to gel.

The number of terminal double bonds referred to herein can be known from a product specification of the crosslinking agent used. Specific examples of the number of terminal double bonds referred to herein include a value representing an average value of double bonds per one molecule in a whole crosslinking agent present in 1 mol of the crosslinking agent.

Specific examples of the crosslinking agent used in the present exemplary embodiment include trialkenyl isocyanurate compounds such as triallyl isocyanurate (TAIC), polyfunctional methacrylate compounds having two or more methacrylic groups in a molecule, polyfunctional acrylate compounds having two or more acrylic groups in a molecule, vinyl compounds (polyfunctional vinyl compounds) having two or more vinyl groups in a molecule, and vinylbenzyl compounds, such as styrene and divinylbenzene, having a vinylbenzyl group in a molecule. Specifically, preferred are a trialkenyl isocyanurate compound, a polyfunctional acrylate compound, a polyfunctional methacrylate compound, and a polyfunctional vinyl compound. Use of these compounds is considered to more suitably form a crosslink through a curing reaction to further enhance the heat resistance of a cured product of the curable composition according to the present exemplary embodiment. The crosslinking agents exemplified may be used alone, or two or more of the crosslinking agents may be used in combination.

A content of the crosslinking agent ranges preferably from 10 parts by mass to 70 parts by mass, inclusive, more preferably from 10 parts by mass to 50 parts by mass, inclusive, relative to 100 parts by mass of the radically polymerizable compound. When the curable composition contains, as the radically polymerizable compound, the modified polyphenylene ether compound and the crosslinking agent, a content proportion by mass of the modified polyphenylene ether compound to a total of the modified polyphenylene ether compound and the crosslinking agent ranges preferably from 30% to 90%, inclusive, more preferably from 50% to 90%, inclusive. The radically polymerizable compound having a content of the crosslinking agent in the ranges described above affords the curable composition that gives a cured product more excellent in heat resistance and flame retardancy. This is considered to be because the curing reaction of the radically polymerizable compound suitably proceeds.

The curable composition according to the present exemplary embodiment may contain the radically polymerizable compound including, for example, the modified polyphenylene ether compound and the crosslinking agent, and the insoluble phosphorus compound. The curable composition may further contain another component as long as the curable composition contains the radically polymerizable compound and the insoluble phosphorus compound. As the other component, there can be exemplified, in addition to the soluble phosphorus compound, a reaction initiator, a filler, and an additive.

The curable composition according to the present exemplary embodiment may contain a reaction initiator as described above. In the curable composition that contains no reaction initiator, a polymerization reaction (curing reaction) of the radically polymerizable compound may proceed. Depending on a process condition, however, because there are cases where it is difficult to increase the temperature until the curing reaction proceeds, the reaction initiator may be added. The reaction initiator is not particularly limited as long as the polymerization reaction of the radically polymerizable compound can be promoted. As the reaction initiator, for example, a peroxide is preferably used. Examples of the reaction initiator include α,α′-bis(t-butylperoxy-m-isopropyl)benzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile. As the reaction initiator, for example, a metal carboxylate can be used in combination, as needed. Such combination use can further promote the curing reaction.

Among these examples, preferred are α,α′-bis(t-butylperoxy-m-isopropyl)benzene, 2,5-dimethyl-2,5-di(t-butylperoxy)-3-hexyne, and benzoyl peroxide, and more preferred is α,α′-bis(t-butylperoxy-m-isopropyl)benzene. As having a relatively high reaction start temperature, α,α′-bis(t-butylperoxy-m-isopropyl)benzene can suppress promotion of the curing reaction when curing is not required, e.g., during prepreg drying, to suppress deterioration in preserving properties of the curable composition. Further, as having low volatility, α,α′-bis(t-butylperoxy-m-isopropyl)benzene does not volatilize during prepreg drying and preservation, to be excellent in stability. One reaction initiator may be used alone, or two or more reaction initiators may be used in combination.

A content of the reaction initiator ranges preferably from 0 parts by mass to 10 parts by mass, inclusive, more preferably from 0.5 parts by mass to 5 parts by mass, inclusive, relative to 100 parts by mass of the organic component. The reaction initiator is not necessarily contained as described above. The curable composition having a too low content of the reaction initiator, however, is unlikely to be capable of sufficiently exhibiting the effects brought about by containing the reaction initiator. The curable composition having a too high content of the reaction initiator is likely to adversely affect the dielectric properties or the heat resistance of a cured product obtained.

The curable composition according to the present exemplary embodiment may contain a filler as described above. As the filler, there can be exemplified one that is added to enhance the heat resistance or the flame retardancy of a cured product of the curable composition, and the filler is not particularly limited. Addition of the filler can further enhance, for example, the heat resistance or the flame retardancy of a cured product. Specific examples of the filler include metal oxides such as silica (e.g., spherical silica), alumina, titanium oxide, and mica, metal hydroxides such as aluminum hydroxide and magnesium hydroxide, talc, aluminum borate, barium sulfate, and calcium carbonate. Among these examples, the filler is preferably silica, mica, or talc, more preferably spherical silica. One filler may be used alone, or two or more fillers may be used in combination. The filler may be used as it is or may be used after subjected to a surface treatment with a silane coupling agent of, for example, an epoxysilane or aminosilane type. The silane coupling agent is preferred to be of a vinylsilane type, a methacryloxysilane type, an acryloxysilane type, and a styrylsilane type, from the viewpoint of the reactivity with the radically polymerizable compound. The surface-treated filler enhances the adhesion strength to a metal foil and interlayer adhesion strength between resins. As the filler, use of, instead of one that is to be subjected to a surface treatment preliminarily, one to which the silane coupling agent has been added by an integral blending method provides an effect of a surface treatment.

When the filler is contained, a content of the filler ranges preferably from 10 parts by mass to 200 parts by mass, inclusive, more preferably from 30 parts by mass to 150 parts by mass, inclusive, relative to a total 100 parts by mass of the organic component (excluding the flame retardant) and the flame retardant.

The curable composition according to the present exemplary embodiment may contain an additive as described above. Examples of the additive include defoaming agents such as a silicone-based defoaming agent and an acrylic acid ester-based defoaming agent, an antioxidant, a heat stabilizer, an antistatic agent, an ultraviolet absorber, a dye and a pigment, a lubricant, and a wetting dispersant.

The curable composition according to the present exemplary embodiment may be used after prepared into varnish. For example, when a prepreg is produced, the curable composition may be used after prepared into varnish, for purpose of impregnating with the curable composition a base material (fibrous base material) for forming the prepreg. That is, the curable composition may be used after prepared into varnish. Such a varnish composition is prepared as follows, for example.

First, components that can be dissolved in an organic solvent are added to and dissolved in the organic solvent. This procedure may be conducted with heating, as needed. Subsequently, a component that is used as needed and does not dissolve in the organic solvent, such as an inorganic filler, is added to and dispersed in the resulting mixed solution with use of, for example, a ball mill, a bead mill, a planetary mixer, or a roller mill, until the solution becomes a predetermined dispersed state. Thus, a varnish composition is prepared. The organic solvent used herein is not particularly limited as long as the organic solvent dissolves the radically polymerizable compound and does not inhibit the curing reaction. Specific examples of the organic solvent include toluene and methyl ethyl ketone (MEK).

With use of the curable composition according to the present exemplary embodiment, it is possible to obtain, as described below, a prepreg, a composition-coated metal foil (metal foil with a resin), a resin plate, a metal-clad laminate, and a wiring board. When these items are produced, the varnish composition as described above may be used as the curable composition.

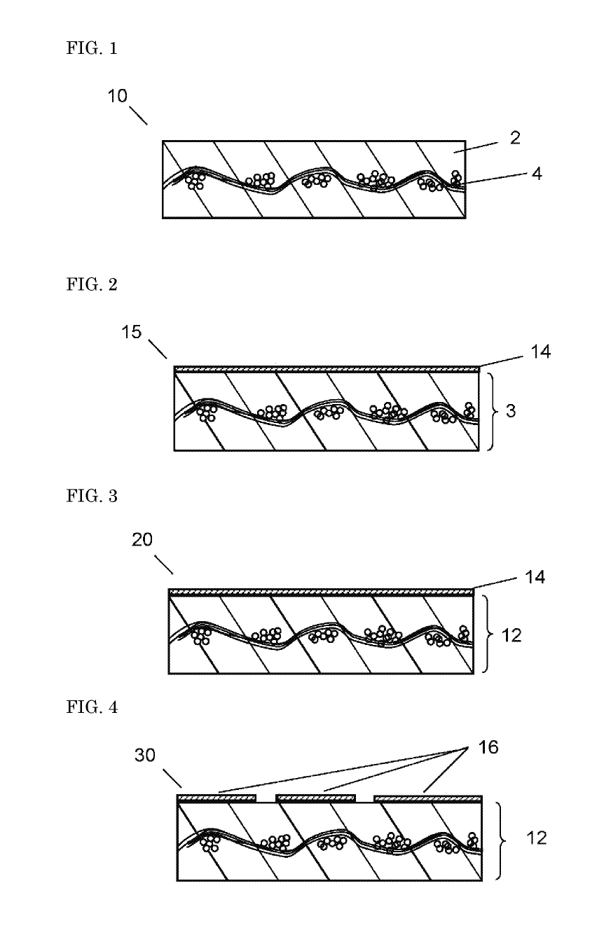

FIG. 1 is a schematic sectional view illustrating prepreg 10 according to the present exemplary embodiment. Prepreg 10 includes curable composition 2 and fibrous base material 4 impregnated with curable composition 2. Curable composition 2 may be a half-cured product of the curable composition. As prepreg 10, there can be exemplified one in which the fibrous base material is present in the half-cured product. That is, prepreg 10 includes the half-cured product and the fibrous base material present in the half-cured product.

The half-cured product referred to is a product obtained by partway curing the curable composition to such an extent that the product can be further cured. That is, the half-cured product is a half-cured state of the curable composition. That is, the half-cured product is in a stage B. For example, the curable composition gradually decreases the viscosity at first when heated, and subsequently starts to be cured with a gradual increase of viscosity. In such a case, half curing refers to, for example, a state from the viscosity starting to increase to before the curable composition being completely cured.

The prepreg obtained with use of the curable composition according to the present exemplary embodiment may include a half-cured product of the curable composition as described above or may include the curable composition that is not yet cured. That is, the prepreg may include the half-cured product of the curable composition (curable composition in the stage B) and the fibrous base material or may include the curable composition that is uncured (curable composition in a stage A) and the fibrous base material. Specific examples of the prepreg include one in which the fibrous base material is present in the curable composition.

A method for producing the prepreg according to the present exemplary embodiment is not particularly limited as long as the method can produce the prepreg. Exemplified is a method of impregnating the fibrous base material with the curable composition according to the present exemplary embodiment, e.g., the curable composition that has been prepared into varnish. That is, examples of the prepreg according to the present exemplary embodiment include one obtained by impregnating the fibrous base material with the curable composition. An impregnation method is not particularly limited as long as the method enables impregnation of the fibrous base material with the curable composition. The impregnation method is not limited to dipping, and examples of the impregnation method include rolling, die coating, bar coating, and spraying. As the method for producing the prepreg, the fibrous base material that has been impregnated with the curable composition may be dried or heated after the impregnation. That is, examples of the method for producing the prepreg include a method of impregnating the fibrous base material with the curable composition that has been prepared into varnish and then drying the fibrous base material, a method of impregnating the fibrous base material with the curable composition that has been prepared into varnish and then heating the fibrous base material, and a method of impregnating the fibrous base material with the curable composition that has been prepared into varnish, and drying and then heating the fibrous base material.

Specific examples of the fibrous base material used in the production of the prepreg include glass cloth, aramid cloth, polyester cloth, nonwoven glass fabric, nonwoven aramid fabric, nonwoven polyester fabric, pulp paper, and linter paper. Use of glass cloth gives a laminate excellent in mechanical strength. In particular, glass cloth subjected to a flattening treatment is preferable. Specific examples of the flattening treatment include continuously applying an appropriate level of pressure to glass cloth with a press roll to compress yarns of the glass cloth flat. A thickness of the fibrous base material that can generally be used ranges from 0.02 mm to 0.3 mm, for example.

The fibrous base material is impregnated with the curable composition by, for example, immersion or application. This impregnation can be repeated a plurality of times, as needed. In this case, it is possible to adjust the composition and an amount to be impregnated of the curable composition to finally intended ones by repeating the impregnation with use of a plurality of curable compositions different in composition and concentration.

The fibrous base material that has been impregnated with the curable composition is heated under desired heating conditions, e.g., a temperature ranging from 80° C. to 180° C. for a period ranging from 1 minute to 10 minutes, to give the prepreg in the half-cured state (stage B).

Such a prepreg can realize a metal-clad laminate and a wiring board that are excellent in dielectric properties, heat resistance, flame retardancy, adhesion strength, and chemical resistance.

FIG. 2 is a schematic sectional view illustrating composition-coated metal foil 15 (metal foil with a resin) according to the present exemplary embodiment. Composition-coated metal foil 15 includes composition layer 3 including the curable composition, and metal foil 14. The curable composition may be a half-cured product of the curable composition. Composition-coated metal foil 15 includes metal foil 14 on a surface of composition layer 3. That is, composition-coated metal foil 15 includes composition layer 3 and metal foil 14 laminated on composition layer 3. Composition-coated metal foil 15 may also include another layer between composition layer 3 and metal foil 4.

Composition layer 3 may include the half-cured product of the curable composition as described above or may include the curable composition that is not yet cured. That is, the composition-coated metal foil may include the half-cured product of the curable composition (curable composition in the stage B) and the metal foil or may include the composition layer including the curable composition that is uncured (curable composition in the stage A), and the metal foil. The composition layer should include at least the curable composition or the half-cured product of the curable composition, and may or may not include a fibrous base material. As the fibrous base material, the same fibrous base material as in the prepreg can be used.

As metal foil 14, it is possible to use, without any limitation, a metal foil that can be used for the composition-coated metal foil (metal foil with the resin) and a metal-clad laminate. Examples of metal foil 14 include a copper foil and an aluminum foil.

A method for producing the composition-coated metal foil according to the present exemplary embodiment is not particularly limited as long as the method can produce the composition-coated metal foil. Examples of the method for producing the metal foil include a method of applying onto the metal foil the curable composition according to the present exemplary embodiment, e.g., the curable composition that has been prepared into varnish. That is, the composition-coated metal foil according to the present exemplary embodiment can be obtained by, for example, applying the curable composition to the metal foil. An application method is not particularly limited as long as the method enables application of the curable composition to the metal foil. Examples of the application method include rolling, die coating, bar coating, and spraying. As the method for producing the composition-coated metal foil, the metal foil to which the curable composition has been applied may be dried or heated after the application. That is, examples of the method for producing the composition-coated metal foil include a method of applying onto the metal foil the curable composition that has been prepared into varnish and then drying the metal foil, a method of applying onto the metal foil the curable composition that has been prepared into varnish and then heating the metal foil, and a method of applying onto the metal foil the curable composition that has been prepared into varnish, and drying and then heating the metal foil.

The metal foil to which the curable composition has been applied is heated under desired heating conditions, e.g., a temperature ranging from 80° C. to 180° C. for a period ranging from 1 minute to 10 minutes, to give the composition-coated metal foil in the half-cured state (stage B).

Use of such a composition-coated metal foil can realize a metal-clad laminate and a wiring board that are excellent in dielectric properties, heat resistance, flame retardancy, adhesion strength, and chemical resistance.

FIG. 3 is a schematic sectional view illustrating metal-clad laminate 20 according to the present exemplary embodiment. Metal-clad laminate 20 includes insulating layer 12 including a cured product of the curable composition, and metal foil 14. Metal-clad laminate 20 includes metal foil 14 on a surface of insulating layer 12. That is, metal-clad laminate 20 includes insulating layer 12 and metal foil 14 laminated on insulating layer 12. Metal-clad laminate 20 may include another layer between insulating layer 12 and metal foil 14.

Insulating layer 12 should include at least the cured product of the curable composition, and may or may not include a fibrous base material. As the fibrous base material, the same fibrous base material as in the prepreg can be used. As metal foil 14, the same metal foil as in the composition-coated metal foil (metal foil with the resin) can be used.

A method for producing the metal-clad laminate according to the present exemplary embodiment is not particularly limited as long as the method can produce the metal-clad laminate. Exemplified is a method of using the prepreg. Examples of the method for manufacturing the metal-clad laminate with use of the prepreg include a method of stacking a prepreg or a plurality of prepregs with a metal foil such as a copper foil stacked on both or one surface of the stacked body and integrally laminating the stacked body by hot-press molding. This method can manufacture a laminate both surfaces or one surface of which is clad with the metal foil. That is, the metal-clad laminate according to the present exemplary embodiment can be obtained by stacking the metal foil on the prepreg and subjecting the stacked body to hot-press molding. A hot press condition can appropriately be set according to at least one of, for example, a thickness of the laminate to be produced and a type of the curable composition in the prepreg. For example, the temperature can be set to range from 170° C. to 210° C., the pressure to range from 1.5 MPa to 4.0 MPa, and the period to range from 60 minutes to 150 minutes. The metal-clad laminate may be produced without using the prepreg. Examples of the method for producing the metal-clad laminate without using the prepreg include a method of applying onto the metal foil the curable composition such as a varnish curable composition to form on the metal foil a layer including the curable composition, and then hot-pressing the metal foil on which the layer has been formed.

Such a metal-clad laminate can realize a wiring board excellent in dielectric properties, heat resistance, flame retardancy, adhesion strength, and chemical resistance.

The curable composition according to the present exemplary embodiment is excellent in dielectric properties, heat resistance, flame retardancy, adhesion strength between cured products, adhesion strength to, for example, a metal, and chemical resistance. Therefore, the prepreg obtained with use of the curable composition can realize the metal-clad laminate excellent in dielectric properties, heat resistance, flame retardancy, adhesion strength between cured products, adhesion strength to, for example, a metal, and chemical resistance. The metal-clad laminate including the prepreg can realize a wiring board excellent in dielectric properties, heat resistance, flame retardancy, adhesion strength between layers that constitute the laminate, adhesion strength to, for example, a metal, and chemical resistance.

FIG. 4 is a schematic sectional view illustrating wiring board 30 according to the present exemplary embodiment. Wiring board 30 includes insulating layer 12 including a cured product of the curable composition, and wiring 16. Wiring board 30 includes wiring 16 on a surface of the insulating layer. That is, wiring board 30 includes insulating layer 12 and wiring 16 laminated on insulating layer 12. Wiring board 30 may include another layer between insulating layer 12 and wiring 16.

Insulating layer 12 should include at least the cured product of the curable composition, and may or may not include a fibrous base material. As the fibrous base material, the same fibrous base material as in the prepreg can be used.

Wiring 16 is not particularly limited as long as the wiring can be provided in the wiring board. Exemplified is wiring formed by partially removing the metal foil laminated on the insulating layer. Examples of wiring 16 include wiring formed by a method such as a subtractive method, an additive method, a semiadditive method, chemical mechanical polishing (CMP), trench, an ink-jet technique, squeegee, or transfer.

A method for producing the wiring board according to the present exemplary embodiment is not particularly limited as long as the method can produce the wiring board. Exemplified is a method of using the metal-clad laminate. Examples of the method for manufacturing the wiring board with use of the metal-clad laminate include a method of subjecting the metal foil on a surface of the metal-clad laminate to etching to form a circuit. This method can give the wiring board that is the metal-clad laminate on the surface of which a conductor pattern is provided as a circuit. That is, the wiring board according to the present exemplary embodiment can be obtained by partially removing the metal foil on the surface of the metal-clad laminate to form a circuit.

The wiring board thus obtained is excellent in dielectric properties, heat resistance, flame retardancy, and chemical resistance, and peeling of the circuit is sufficiently suppressed.

The curable composition can also be cured into a plate for use as a resin plate. Exemplified is a resin plate obtained by applying a varnish curable composition so as to form a plate, and drying and then curing the plate. As the resin plate, there can also be exemplified an unclad board obtained by removing the metal foil from the metal-clad laminate.

The present exemplary embodiment has disclosed various forms of techniques as described above, and main techniques are especially summarized as follows.

A curable composition according to the present exemplary embodiment includes a radically polymerizable compound having a carbon-carbon unsaturated double bond in a molecule, and an insoluble phosphorus compound insoluble in the radically polymerizable compound. The insoluble phosphorus compound includes a phosphine oxide compound having two or more diphenylphosphine oxide groups in a molecule.

According to such constitution, there can be provided the curable composition that gives a cured product excellent in dielectric properties, heat resistance, flame retardancy, adhesion strength, and chemical resistance. That is, even when a flame retardant is added to enhance the flame retardancy, the resin curable composition can be obtained that gives a cured product excellent in adhesion strength to, for example, a metal foil provided on the cured product or adhesion strength between cured products and in chemical resistance while the cured product maintaining excellent dielectric properties and heat resistance.

This is considered to be due to following reasons.

The curable composition contains, as the flame retardant, instead of a soluble phosphorus compound soluble in the radically polymerizable compound, an insoluble phosphorus compound insoluble in the radically polymerizable compound. This is considered to suppress generation of a defect caused when only the soluble phosphorus compound is added in attempt to allow the flame retardancy to be sufficiently exhibited. As the insoluble phosphorus compound is contained a phosphine oxide compound having two or more diphenylphosphine oxide groups in a molecule. Such a flame retardant that is an insoluble phosphorus compound but is not a salt is considered to suppress a decrease in adhesion strength and chemical resistance. Even when a flame retardant is added to secure the flame retardancy, the curable composition is considered to sufficiently prevent polymerization by the radically polymerizable compound from being inhibited, as long as the flame retardant is such a flame retardant. Therefore, it is considered that the radically polymerizable compound can suitably be polymerized and does not newly generate a polar group such as a hydroxy group in a cured product obtained after curing through the polymerization, so that a cured product can be obtained that is excellent in dielectric properties and heat resistance.

As described above, the curable composition is considered to become a composition that can suitably give a cured product excellent in dielectric properties, heat resistance, flame retardancy, adhesion strength between cured products or adhesion strength to, for example a metal, and chemical resistance. An insulating layer provided in a wiring board can be formed with use of such a curable composition to give an excellent wiring board.

In the curable composition, the phosphine oxide compound is preferred to have a melting point of 280° C. or more.

Such arrangement can give the curable composition that provides a cured product having a lower dissipation factor. This is considered to be because use of a flame retardant having a high melting point as the flame retardant to be added increases the melting point of the curable composition. It is considered that the crystallinity increases along with an increase in the melting point of the curable composition to suppress molecular motion, so that the dissipation factor further decreases. For the reasons described above, use of the composition obtained is considered to give a cured product having a lower dissipation factor.

In the curable composition, the phosphine oxide compound is preferred to have, in the molecule, a linking group that connects the two or more diphenylphosphine oxide groups. The linking group is preferred to include at least one selected from the group consisting of a phenylene group, a xylylene group, a biphenylene group, a naphthylene group, a methylene group, and an ethylene group.

According to such constitution, there can be provided the curable composition that gives a cured product more excellent in dielectric properties, heat resistance, flame retardancy, adhesion strength, and chemical resistance.

In the curable composition, the phosphine oxide compound is preferred to be a compound represented by any one of the formulae (1-1) to (1-4).

According to such constitution, there can be provided the curable composition that gives a cured product more excellent in dielectric properties, heat resistance, flame retardancy, adhesion strength, and chemical resistance.

The curable composition is preferred to further contain a soluble phosphorus compound soluble in the radically polymerizable compound.

Such constitution can give the curable composition that provides a cured product higher in flame retardancy. This is because using, as the flame retardant, the soluble phosphorus compound and the insoluble phosphorus compound in combination is considered to give a cured product higher in flame retardancy than when either one of the soluble phosphorus compound and the insoluble phosphorus compound is used. Further, since the curable composition contains the phosphine oxide compound as the insoluble phosphorus compound, the curable composition is considered to give a cured product more excellent in flame retardancy while the cured product maintaining excellent heat resistance, even when the curable composition containing the soluble phosphorus compound to decrease the heat resistance such as a little decrease in glass transition temperature. Therefore, the curable composition is considered to give a cured product higher in flame retardancy while the cured product maintaining excellent heat resistance.

In the curable composition, a content proportion by mass of the insoluble phosphorus compound to a total of the insoluble phosphorus compound and the soluble phosphorus compound preferably ranges from 20% to 80%, inclusive.

According to such constitution, there can be provided the curable composition that gives a cured product more excellent in heat resistance and flame retardancy. This is considered to be because the effect can be more exhibited that is brought about by using, as the flame retardant, the soluble phosphorus compound and the insoluble phosphorus compound in combination.

In the curable composition, the soluble phosphorus compound is preferred to be at least one selected from the group consisting of a phosphoric acid ester compound, a phosphazene compound, a phosphorous acid ester compound, and a phosphine compound.

According to such constitution, there can be provided the curable composition that gives a cured product more excellent in dielectric properties, heat resistance, flame retardancy, adhesion strength, and chemical resistance.

In the curable composition, a content of a phosphorus atom preferably ranges from 1.8% by mass to 5.2% by mass relative to a whole organic component.

According to such constitution, there can be provided the curable composition that can give a cured product higher in flame retardancy while the cured product maintaining, for example, excellent dielectric properties and heat resistance. This is considered to be because such a curable composition can sufficiently enhance the flame retardancy while sufficiently suppressing a decrease in, for example, dielectric properties and heat resistance that is caused by containing the flame retardant. Therefore, the curable composition is considered to be obtained that gives a cured product more excellent in flame retardancy while the cured product maintaining dielectric properties, heat resistance, adhesion strength, and chemical resistance.

In the curable composition, the radically polymerizable compound is preferred to include a modified polyphenylene ether compound terminally modified with a substituent having a carbon-carbon unsaturated double bond, and a crosslinking agent having two or more carbon-carbon unsaturated double bonds in a molecule.

According to such constitution, there can be provided the curable composition that gives a cured product more excellent in heat resistance, flame retardancy, adhesion strength, and chemical resistance while the cured product maintaining excellent dielectric properties of a polyphenylene ether.

This is considered to be due to following reasons.

The modified polyphenylene ether compound is crosslinked by radically polymerizing the carbon-carbon unsaturated double bond at a terminal of the modified polyphenylene ether compound with a carbon-carbon unsaturated double bond of the crosslinking agent. A cured product obtained by this crosslink is considered to be capable of exhibiting excellent dielectric properties because the cured product has a polyphenylene ether derived from the modified polyphenylene ether compound. It is considered that due to the radical polymerization of the modified polyphenylene ether compound with use of the crosslinking agent, a crosslinking reaction is suitably promoted to give a cured product in which a suitable crosslinked structure is formed. Therefore, it is considered that the cured product obtained becomes higher in glass transition temperature to become more excellent in heat resistance. Further, it is considered that even in such radical polymerization, it is possible to sufficiently prevent the polymerization from being inhibited even when the flame retardant is added as long as the flame retardant is such a flame retardant. For the reasons described above, it is considered that the radical polymerization of the modified polyphenylene ether compound with the crosslinking agent suitably proceeds without newly generating a polar group such as a hydroxy group in a cured product obtained after curing through the polymerization, so that the cured product can be obtained that is excellent in dielectric properties and heat resistance. Therefore, the curable composition is considered to be obtained that gives a cured product more excellent in heat resistance, flame retardancy, adhesion strength, and chemical resistance while the cured product maintaining excellent dielectric properties of the polyphenylene ether.

In the curable composition, the modified polyphenylene ether compound is preferred to have a weight average molecular weight ranging from 500 to 5000, inclusive, and an average of 1 to 5, inclusive, substituents in one molecule.

According to such constitution, there can be provided the curable composition that gives a cured product more excellent in heat resistance, flame retardancy, adhesion strength, and chemical resistance while the cured product maintaining excellent dielectric properties of a polyphenylene ether. Further, the curable composition obtained is also excellent in moldability.

In the curable composition, the substituent at the terminal of the modified polyphenylene ether compound is preferred to be a substituent having at least one selected from the group consisting of a vinylbenzyl group, an acrylate group, and a methacrylate group.

According to such constitution, there can be provided the curable composition that gives a cured product more excellent in heat resistance, flame retardancy, adhesion strength, and chemical resistance while the cured product maintaining excellent dielectric properties of a polyphenylene ether.

In the curable composition, a content ratio by mass between the modified polyphenylene ether compound and the crosslinking agent preferably ranges from 30% to 90%, inclusive.

According to such constitution, there can be provided the curable composition that gives a cured product more excellent in heat resistance, flame retardancy, adhesion strength, and chemical resistance while the cured product maintaining excellent dielectric properties of a polyphenylene ether.

In the curable composition, the crosslinking agent is preferred to be at least one selected from the group consisting of a trialkenyl isocyanurate compound, a polyfunctional acrylate compound having two or more acrylic groups in a molecule, a polyfunctional methacrylate compound having two or more methacrylic groups in a molecule, and a polyfunctional vinyl compound having two or more vinyl groups in a molecule.

According to such constitution, there can be provided the curable composition that gives a cured product more excellent in heat resistance, flame retardancy, adhesion strength, and chemical resistance while the cured product maintaining excellent dielectric properties of a polyphenylene ether.

In the curable composition, the radically polymerizable compound is preferred to be a polymer of a conjugated diene or a copolymer of a conjugated diene with a vinyl aromatic compound.

According to such constitution, there can be provided the curable composition that gives a cured product more excellent in dielectric properties, heat resistance, flame retardancy, adhesion strength, and chemical resistance.

The curable composition is preferred to further contain a peroxide.

Such constitution can promote a curing reaction of the curable composition. Therefore, it is possible to obtain, in a shorter period, a cured product excellent in dielectric properties, heat resistance, flame retardancy, adhesion strength, and chemical resistance.

A prepreg according to the present exemplary embodiment includes the curable composition or a half-cured product of the curable composition, and a fibrous base material impregnated with the curable composition or the half-cured product.

Such arrangement can give the prepreg that can realize a metal-clad laminate excellent in dielectric properties, heat resistance, flame retardancy, adhesion strength, and chemical resistance.

A composition-coated metal foil according to the present exemplary embodiment includes a composition layer including the curable composition or a half-cured product of the curable composition, and a metal foil laminated on the composition layer.

Such arrangement can give the composition-coated metal foil that can realize a metal-clad laminate and a wiring board that are excellent in dielectric properties, heat resistance, flame retardancy, adhesion strength, and chemical resistance.

A metal-clad laminate according to the present exemplary embodiment includes an insulating layer including a cured product of the curable composition, and a metal foil laminated on the insulating layer.

Such arrangement can give the metal-clad laminate that can realize a wiring board excellent in dielectric properties, heat resistance, flame retardancy, adhesion strength, and chemical resistance.

A wiring board according to the present exemplary embodiment includes an insulating layer including a cured product of the curable composition, and wiring laminated on the insulating layer.

Such arrangement can give the wiring board that includes the insulating layer excellent in dielectric properties, heat resistance, flame retardancy, adhesion strength, and chemical resistance and that can sufficiently suppress peeling of a circuit from the insulating layer.

Hereinafter, the present exemplary embodiment is further specifically described by way of examples. Scope of the present invention, however, is not limited to these examples.

### EXAMPLES

### Examples 1 to 18 and Comparative Examples 1 to 7

### [Preparation of Curable Composition]

Components used for preparing a curable composition in the present examples are described.

### (Radically Polymerizable Compound)

Modified PPE1: a modified polyphenylene ether obtained by modifying a terminal hydroxy group of a polyphenylene ether with a methacrylic group (SA9000 manufactured by SABIC Innovative Plastics, Mw 1700, 1.8 terminal functional groups).
Modified PPE2: a modified polyphenylene ether obtained by reacting a polyphenylene ether with chloromethylstyrene
   Specifically, modified PPE2 is a modified polyphenylene ether obtained through a reaction described below.

First, into a 1-L three-necked flask equipped with a temperature controller, a stirring device, a cooling unit, and a tap funnel are charged 200 g of a polyphenylene ether (SA90 manufactured by SABIC Innovative Plastics, 1.8 terminal hydroxy groups, Mw 1700), 30 g of a mixture of p-chloromethylstyrene and m-chloromethylstyrene (chloromethylstyrene (CMS) manufactured by Tokyo Chemical Industry Co., Ltd.) at a ratio by mass of 50:50, 1.227 g of tetra-n-butylammonium bromide as a phase-transfer catalyst, and 400 g of toluene, followed by stirring. The stirring is conducted until the polyphenylene ether, chloromethylstyrene, and tetra-n-butylammonium bromide are dissolved in toluene. During the stirring, the mixture is gradually heated until a liquid temperature reaches 75° C. in the end. To the resulting solution, an aqueous sodium hydroxide solution (20 g of sodium hydroxide/20 g of water) as an alkali metal hydroxide is added dropwise over 20 minutes. Then, stirring is conducted for another 4 hours at 75° C. Next, contents of the flask is neutralized with 10%-by-mass hydrochloric acid, followed by addition of a great amount of methanol. This procedure generates a precipitate in the liquid of the flask. In other words, this procedure reprecipitates a product contained in the reaction liquid of the flask. The precipitate is taken out by filtration, washed three times with a mixed liquid of methanol and water at a ratio by mass of 80:20, and then dried under reduced pressure at 80° C. for 3 hours.

The resulting solid is subjected to ¹H-NMR (Nuclear Magnetic Resonance) analysis (400 MHz, CDCl₃, TMS). As the result of NMR measurement, a peak attributable to a vinylbenzyl group (ethenylbenzyl group) is observed at 5 ppm to 7 ppm. Thus, the solid obtained can be identified to be a modified polyphenylene ether having, at a molecular terminal of a molecule, the vinylbenzyl group as a substituent. Specifically, the solid obtained can be identified to be an ethenylbenzylated polyphenylene ether.

A number of terminal functional groups in the modified polyphenylene ether is measured as follows.

First, the modified polyphenylene ether is accurately weighed. The weight is defined as X (mg). The modified polyphenylene ether thus weighed is dissolved in 25 mL of methylene chloride. To the resulting solution is added 100 μL of an ethanol solution containing 10% by mass of tetraethylammonium hydroxide (TEAH) (volume ratio of TEAH:ethanol=15:85). Then, the resulting solution was measured for absorbance (Abs) at 318 nm with use of a UV (Ultra Violet) spectrophotometer (UV-1600 manufactured by SHIMADZU CORPORATION). Based on the measurement result, the number of terminal hydroxy groups in the modified polyphenylene ether is calculated according to a following equation.

Remaining OH amount (μmol/g)=[(25×Abs)/(ε×OPL×X)]×10⁶

Here, ε represents an absorption coefficient and is 4700 L/mol·cm. OPL (Optical Path Length) is cell optical path length and is 1 cm.

The remaining OH amount (the number of terminal hydroxy groups) in the modified polyphenylene ether thus calculated is near zero, which indicates that almost all the hydroxy groups in the unmodified polyphenylene ether have been modified. This result indicates that a decrease in the number of terminal hydroxy groups from the unmodified polyphenylene ether is the number of terminal hydroxy groups in the unmodified polyphenylene ether. That is, this results indicates that the number of terminal hydroxy groups in the unmodified polyphenylene ether is the number of terminal functional groups in the modified polyphenylene ether. That is, the number of terminal functional groups is 1.8.

The modified polyphenylene ether is measured for intrinsic viscosity (IV) in methylene chloride at 25° C. Specifically, the intrinsic viscosity (IV) of the modified polyphenylene ether is measured by subjecting a solution containing the modified polyphenylene ether and methylene chloride at a concentration of 0.18 g/45 ml (liquid temperature 25° C.) to measurement with a viscometer (AVS500 Visco System manufactured by SCHOTT Instruments GmbH). As the result, the intrinsic viscosity of the modified polyphenylene ether is 0.086 dl/g.

The modified polyphenylene ether is measured for a molecular weight distribution with use of GPC. An Mw is calculated from the molecular weight distribution obtained. As the result, the Mw is 1900.
Modified PPE-3: synthesized in the same method as in the synthesis of the modified PPE-2 except for using a polyphenylene ether described below as the polyphenylene ether and conducting the synthesis under conditions described below.

The polyphenylene ether used is a polyphenylene ether (SA120 manufactured by SABIC Innovative Plastics, intrinsic viscosity 0.125 dl/g, 1 terminal hydroxy group, Mw 2400).

Next, the reaction between the polyphenylene ether and the chloromethylstyrene is conducted by using 200 g of the polyphenylene ether, 15 g of CMS, and 0.92 g of tetra-n-butylammonium bromide as a phase-transfer catalyst, and the modified PPE-3 is synthesized in the same method as in the synthesis of the modified PPE-2 except for using, in place of the aqueous sodium hydroxide solution (20 g of sodium hydroxide and 20 g of water), an aqueous sodium hydroxide solution (10 g of sodium hydroxide and 10 g of water).

The resulting solid is subjected to ¹H-NMR (Nuclear Magnetic Resonance) analysis (400 MHz, CDCl₃, TMS). As the result of NMR measurement, a peak attributable to an ethenylbenzyl group is observed at 5 ppm to 7 ppm. Thus, the solid obtained can be identified to be a modified polyphenylene ether having in a molecule a vinylbenzyl group as a substituent. Specifically, the solid obtained can be identified to be an ethenylbenzylated polyphenylene ether.

The number of terminal functional groups in the modified polyphenylene ether is measured in the same method as described above. As the result, the number of terminal functional groups is 1.

The modified polyphenylene ether is measured for the intrinsic viscosity in methylene chloride at 25° C. in the same method as the method described above. As the result, the intrinsic viscosity of the modified polyphenylene ether is 0.125 dl/g.

The Mw of the modified polyphenylene ether is measured in the same method as the method described above. As the result, the Mw is 2800.
TAIC: triallyl isocyanurate (TAIC manufactured by Nippon Kasei Chemical Company Limited, monomer, liquid, molecular weight 249, 3 terminal double bonds)
DVB: divinylbenzene (DVB-810 manufactured by NIPPON STEEL & SUMITOMO METAL CORPORATION, monomer, liquid, molecular weight 130, 2 terminal double bonds)
Polybutadiene: Ricon 150 manufactured by Cray Valley USA, LLC
Butadiene-styrene copolymer: Ricon 181 manufactured by Cray Valley USA, LLC

### (Insoluble Phosphorus Compound)

Phosphine oxide compound 1 (PQ-60 manufactured by Chin Yee Chemical Industries Ltd., a compound (para-xylylene bisdiphenylphosphine oxide) represented by the formula (13), melting point 330° C.)
Phosphine oxide compound 2 (BPO-13 manufactured by KATAYAMA CHEMICAL INDUSTRIES Co., Ltd., a compound (para-phenylene bisdiphenylphosphine oxide) represented by the formula (14), melting point 300° C.)
Phosphine oxide compound 3 (BPE-3 manufactured by KATAYAMA CHEMICAL INDUSTRIES Co., Ltd., a compound (ethylene bisdiphenylphosphine oxide) represented by the formula (15), melting point 270° C.)
Phosphinate compound: aluminum trisdiethylphosphinate (Exolit OP-935 manufactured by Clariant (Japan) K.K., phosphorus concentration 23% by mass)
Polyphosphate compound: melamine polyphosphate (Melapur 200 manufactured by BASF Corporation, phosphorus concentration 13% by mass)

### (Soluble Phosphorus Compound)

Triphenylphosphine oxide (TPPO manufactured by HOKKO CHEMICAL INDUSTRY CO., LTD., melting point 157° C.)
Phosphoric acid ester compound: aromatic condensed phosphoric acid ester compound (PX-200 manufactured by DAIHACHI CHEMICAL INDUSTRY CO., LTD.: phosphorus concentration 9% by mass)
Phosphazene compound: cyclic phosphazene compound (SPB-100 manufactured by Otsuka Chemical Co., Ltd., phosphorus concentration 13% by mass)

### (Reaction Initiator, Peroxide)

Peroxide: 1,3-bis(butylperoxyisopropyl)benzene (PERBUTYL P manufactured by NOF CORPORATION)

### [Method for Preparation]

First, components other than the peroxide are added to toluene and mixed in the composition (blending ratio) shown in Tables 1 to 4 so that a concentration of solid content becomes 60% by mass. The resulting mixture is heated to 80° C., and stirred for 60 minutes while the temperature is kept at 80° C. After the mixture that has been stirred is cooled to 40° C., the peroxide is added to attain the composition (blending ratio) shown in Tables 1 to 4, so that a varnish curable composition can be obtained.

Next, glass cloth (#2116 type WEA116E manufactured by NITTO BOSEKI CO., LTD, E-glass, thickness 0.1 mm) is impregnated with the resulting varnish curable composition, and then heated and dried at a temperature ranging from 100° C. to 160° C. for about 2 minutes to about 8 minutes, to give a prepreg. In this procedure, a content of the organic components in, for example, the radically polymerizable compound is adjusted to become about 50% by mass.

Six prepregs obtained are stacked, and on both sides of the stacked body is disposed a copper foil having a thickness of 35 μm, to give a body to be pressed. The body to be pressed is hot-pressed under conditions of a temperature of 200° C., a period of 2 hours, and a pressure of 3 MPa to give a copper-foil-clad laminate (metal-clad laminate) to both surfaces of which is adhered a copper foil and which has a thickness of about 0.8 mm. This metal-clad laminate is used as a substrate for evaluation.

The prepreg and the substrate for evaluation thus prepared are evaluated by methods shown below.

### [Glass Transition Temperature (Tg)]

First, the Tg of an unclad board is measured. The unclad board is obtained by etching to remove the copper foil on both the surfaces of the substrate for evaluation. Specifically, the Tg of the unclad board is measured with use of viscoelasticity spectrometer “DMS100” manufactured by Seiko Instruments Inc. In the measurement, dynamic viscoelasticity measurement (Dynamic Mechanical Analysis (DMA)) is conducted with a bending module at a frequency of 10 Hz, and the temperature at which tan 6 shows the highest value is defined as the Tg when the temperature is raised from room temperature to 280° C. at a temperature rising rate of 5° C./min.

### [Interlayer Adhesion Strength]

The copper-foil-clad laminate is measured for peeling strength between the first prepreg and the second prepreg that constitute the insulating layer, in accordance with JIS C 6481. A pattern having a width of 10 mm and a length of 100 mm is formed and peeled with a tensile testing tester at a rate of 50 mm/min, at which the peeling strength (peel-strength) is measured. The peel-strength obtained is defined as interlayer adhesion strength. A unit of measurement is kN/m.

### [Dielectric Properties (Dielectric Constant and Dissipation Factor)]

The substrate for evaluation is measured for the dielectric constant and the dissipation factor at 1 GHz by a method in accordance with IPC-TM650-2.5.5.9. Specifically, the dielectric constant and the dissipation factor of the substrate for evaluation are measured at 1 GHz with an impedance analyzer (RF impedance analyzer HP4291B manufactured by Agilent Technologies).

### [Flame Retardancy]

A test piece having a length of 125 mm and a width of 12.5 mm is cut out from the substrate for evaluation. This test piece is subjected to a combustion test 10 times in accordance with “Test for Flammability of Plastic Materials-UL94” of Underwriters Laboratories. Specifically, each of 5 test pieces is subjected to the combustion test twice. The flammability is evaluated according to a total period of combustion duration during the combustion test. The tables show “combustion” for the test piece that has continued to burn to the end.

### [Chemical Resistance: Alkali Resistance]

First, an aqueous 15% by mass sodium solution is heated to 80° C. An unclad board obtained by etching to remove the copper foil on both the surfaces of the substrate for evaluation is immersed for 15 minutes in the aqueous sodium solution that has been heated to 80° C., and then the unclad board is taken out from the aqueous sodium solution. The unclad board is visually checked, to evaluate the unclad board as “OK” when whitening is not observed and as “NG” when whitening is observed. When the unclad board is white and it is difficult to visually check the presence or absence of whitening, the evaluation “NG” is determined for the unclad board having a mass loss rate of 0.5% by mass or more between before and after the immersion. The mass loss rate of the unclad board between before and after the immersion is a proportion of a difference between the mass of the unclad board after the immersion and the mass of the unclad board before the immersion, to the mass of the unclad board before the immersion (mass before immersion−mass after immersion/mass before immersion×100).

### [Heat Resistance: Post-Pressure Cooker Test (PCT) Solder Heat Resistance]

Post-PCT solder heat resistance (moisture absorption solder heat resistance) is measured by a method in accordance with JIS C 6481. Specifically, three sample substrates for evaluation are subjected to the PCT at 121° C. and 2 atmospheric pressure (0.2 MPa) for 6 hours. Each sample is immersed in a solder bath at 260° C. for 20 seconds. The immersed sample is visually observed for the presence or absence of generation of, for example, measling or swelling. The substrate in which the generation of measling or swelling is not observed is evaluated as “OK,” and the substrate in which the generation is observed is evaluated as “NG.” Further, another evaluation is conducted in the same manner with use of a solder bath at 288° C. in place of the solder bath at 260° C.

Tables 1 to 4 show results of the evaluation described above.

TABLE 1

| | | | | Examples | | |
|---|---|---|---|---|---|---|
| | | | | 1 | 2 | 3 |
| Composition | Radically | Modified PPE1 | | 50 | 50 | 50 |
| (part by mass) | polymerizable | TAIC | | 50 | 50 | 50 |
| | compound | | | | | |
| | Insoluble | Phosphine oxide compound 1 | melting | 30 | — | — |
| | phosphorus | | point 330° C. | | | |
| | compound | Phosphine oxide compound 2 | melting | — | 28 | — |
| | | | point 300° C. | | | |
| | | Phosphine oxide compound 3 | melting | — | — | 25 |
| | | | point 270° C. | | | |
| | | Phosphinate compound | | — | — | — |
| | | Polyphosphate compound | | — | — | — |
| | Soluble | Triphenylphosphine oxide | melting | — | — | — |
| | phosphorus | | point 157° C. | | | |

| | | | | |
|---|---|---|---|---|
| compound | Phosphoric acid ester compound | | — | — |
| | Phosphazene compound | — | — | — |
| Peroxide | PERBUTYL P | 2 | 2 | 2 |

| Insoluble phosphorus compound:Soluble phosphorus compound | | | 100:0 | 100:0 | 100:0 |
|---|---|---|---|---|---|
| (ratio by mass) | | | | | |
| Content of phosphorus atom (% by mass) | | | 2.7 | 2.7 | 2.8 |
| Evaluation | Glass transition temperature Tg (° C.) | | 240 | 240 | 240 |
| | Interlayer adhesion strength (kN/m) | | 1.0 | 1.0 | 1.0 |
| | Dielectric constant | | 3.9 | 3.9 | 3.9 |
| | Dissipation factor | | 0.001 | 0.0015 | 0.002 |
| | Flame retardancy (s) | | 110 | 110 | 110 |
| | Chemical resistance | | OK | OK | OK |
| | Heat resistance | 260° C. | OK | OK | OK |
| | | 288° C. | OK | OK | OK |

| | | | | Comparative Examples | | | | |
|---|---|---|---|---|---|---|---|---|
| | | | | 1 | 2 | 3 | 4 | 5 |
| Composition | Radically | Modified PPE1 | | 50 | 50 | 50 | 50 | 50 |
| (part by mass) | polymerizable | TAIC | | 50 | 50 | 50 | 50 | 50 |
| | compound | | | | | | | |
| | Insoluble | Phosphine oxide compound 1 | melting point | — | — | — | — | — |
| | phosphorus | | 330° C. | | | | | |
| | compound | Phosphine oxide compound 2 | melting point | — | — | — | — | — |
| | | | 300° C. | | | | | |
| | | Phosphine oxide compound 3 | melting point | — | — | — | — | — |
| | | | 270° C. | | | | | |
| | | Phosphinate compound | | — | — | 15 | — | 20 |
| | | Polyphosphate compound | | — | — | — | 30 | — |
| | Soluble | Triphenylphosphine oxide | melting point | — | 20 | — | — | — |
| | phosphorus | | 157° C. | | | | | |

| | | | | | | |
|---|---|---|---|---|---|---|
| compound | Phosphoric acid ester compound | — | — | — | — | 15 |
| | Phosphazene compound | — | — | — | — | — |
| Peroxide | PERBUTYL P | 2 | 2 | 2 | 2 | 2 |

| Insoluble phosphorus compound:Soluble phosphorus compound | | | — | 0:100 | 100:0 | 100:0 | 57:43 |
|---|---|---|---|---|---|---|---|
| (ratio by mass) | | | | | | | |
| Content of phosphorus atom (% by mass) | | | 0 | 1.8 | 3.0 | 3.0 | 4.3 |
| Evaluation | Glass transition temperature Tg (° C.) | | 240 | 180 | 240 | 240 | 210 |
| | Interlayer adhesion strength (kN/m) | | 1.0 | 1.0 | 0.6 | 0.8 | 0.6 |
| | Dielectric constant | | 3.9 | 3.9 | 3.9 | 4.2 | 3.9 |
| | Dissipation factor | | 0.002 | 0.002 | 0.002 | 0.002 | 0.002 |
| | Flame retardancy (s) | | Combustion | 152 | 95 | 95 | 25 |
| | Chemical resistance | | OK | OK | NG | NG | NG |
| | Heat resistance | 260° C. | OK | OK | OK | OK | OK |
| | | 288° C. | OK | OK | OK | OK | OK |

TABLE 2

| | | | | Examples | | | |
|---|---|---|---|---|---|---|---|
| | | | | 1 | 4 | 5 | 6 |
| Composition | Radically | Modified PPE1 | | 50 | — | — | 50 |
| (part by mass) | polymerizable | Modified PPE2 | | — | 50 | — | — |
| | compound | Modified PPE3 | | — | — | 50 | — |
| | | TAIC | | 50 | 50 | 50 | — |
| | | DVB | | — | — | — | 50 |
| | Insoluble | Phosphine oxide compound 1 | melting point | 30 | 30 | 30 | 30 |
| | phosphorus | | 330° C. | | | | |
| | compound | | | | | | |

| | | | | | |
|---|---|---|---|---|---|
| Peroxide | PERBUTYL P | 2 | 2 | 2 | 2 |

| Insoluble phosphorus compound:Soluble phosphorus compound | | | 100:0 | 100:0 | 100:0 | 100:0 |
|---|---|---|---|---|---|---|
| (ratio by mass) | | | | | | |
| Content of phosphorus atom (% by mass) | | | 2.7 | 2.7 | 2.7 | 2.7 |
| Evaluation | Glass transition temperature Tg (° C.) | | 240 | 210 | 200 | 230 |
| | Interlayer adhesion strength (kN/m) | | 1.0 | 0.9 | 0.8 | 0.9 |
| | Dielectric constant | | 3.9 | 3.9 | 3.9 | 3.9 |
| | Dissipation factor | | 0.001 | 0.001 | 0.001 | 0.001 |
| | Flame retardancy (s) | | 110 | 110 | 110 | 115 |
| | Chemical resistance | | OK | OK | OK | OK |
| | Heat resistance | 260° C. | OK | OK | OK | OK |
| | | 288° C. | OK | OK | OK | OK |

| | | | | | | | | Comparative |
|---|---|---|---|---|---|---|---|---|
| | | | | Examples | | | | Examples |
| | | | | 7 | 8 | 9 | 10 | 1 |
| Composition | Radically | Modified PPE1 | | 50 | 50 | 90 | 30 | 50 |
| (part by mass) | polymerizable | Modified PPE2 | | — | — | — | — | — |
| | compound | Modified PPE3 | | — | — | — | — | — |
| | | TAIC | | 50 | 50 | 10 | 70 | 50 |
| | | DVB | | — | — | — | — | — |
| | Insoluble | Phosphine oxide compound 1 | melting point | 15 | 80 | 30 | 30 | — |
| | phosphorus | | 330° C. | | | | | |
| | compound | | | | | | | |

| | | | | | | |
|---|---|---|---|---|---|---|
| Peroxide | PERBUTYL P | 2 | 2 | 2 | 2 | 2 |

| Insoluble phosphorus compound:Soluble phosphorus compound | | | 100:0 | 100:0 | 100:0 | 100:0 | — |
|---|---|---|---|---|---|---|---|
| (ratio by mass) | | | | | | | |
| Content of phosphorus atom (% by mass) | | | 1.5 | 5.3 | 2.7 | 2.7 | 0 |
| Evaluation | Glass transition temperature Tg (° C.) | | 240 | 240 | 230 | 220 | 240 |
| | Interlayer adhesion strength (kN/m) | | 1.0 | 0.8 | 1.0 | 1.0 | 1.0 |
| | Dielectric constant | | 3.9 | 3.9 | 3.9 | 3.9 | 3.9 |
| | Dissipation factor | | 0.001 | 0.001 | 0.001 | 0.001 | 0.002 |
| | Flame retardancy (s) | | 150 | 49 | 120 | 95 | Combustion |
| | Chemical resistance | | OK | OK | OK | OK | OK |
| | Heat resistance | 260° C. | OK | OK | OK | OK | OK |
| | | 288° C. | OK | NG | OK | OK | OK |

TABLE 3

| | | | | Examples | | | |
|---|---|---|---|---|---|---|---|
| | | | | 1 | 11 | 12 | 13 |
| Composition | Radically | Modified PPE1 | | 50 | 50 | 50 | 50 |
| (part by mass) | polymerizable | TAIC | | 50 | 50 | 50 | 50 |
| | compound | | | | | | |
| | Insoluble | Phosphine oxide compound 1 | melting point | 30 | 20 | 25 | 3 |
| | phosphorus | | 330° C. | | | | |
| | compound | | | | | | |

| | | | | | |
|---|---|---|---|---|---|
| Soluble | Phosphoric acid ester compound | — | 15 | 15 | 15 |
| phosphorus | Phosphazene compound | — | — | — | — |
| compound | | | | | |
| Peroxide | PERBUTYL P | 2 | 2 | 2 | 2 |

| Insoluble phosphorus compound:Soluble phosphorus compound | | | 100:0 | 57:43 | 62.5:37.5 | 17:83 |
|---|---|---|---|---|---|---|
| (ratio by mass) | | | | | | |
| Content of phosphorus atom (%) | | | 2.7 | 2.7 | 3.1 | 1.4 |
| Evaluation | Glass transition temperature Tg (° C.) | | 240 | 210 | 210 | 210 |
| | Interlayer adhesion strength (kN/m) | | 1.0 | 1.0 | 1.0 | 1.0 |
| | Dielectric constant | | 3.9 | 3.9 | 3.9 | 3.9 |
| | Dissipation factor | | 0.001 | 0.001 | 0.001 | 0.001 |
| | Flame retardancy (s) | | 110 | 56 | 33 | 85 |
| | Chemical resistance | | OK | OK | OK | OK |
| | Heat resistance | 260° C. | OK | OK | OK | OK |
| | | 288° C. | OK | OK | OK | OK |

| | | | | | | | Comparative |
|---|---|---|---|---|---|---|---|
| | | | | Examples | | | Examples |
| | | | | 14 | 15 | 16 | 1 |
| Composition | Radically | Modified PPE1 | | 50 | 50 | 50 | 50 |
| (part by mass) | polymerizable | TAIC | | 50 | 50 | 50 | 50 |
| | compound | | | | | | |
| | Insoluble | Phosphine oxide compound 1 | melting point | 8 | 40 | 20 | — |
| | phosphorus | | 330° C. | | | | |
| | compound | | | | | | |

| | | | | | |
|---|---|---|---|---|---|
| Soluble | Phosphoric acid ester compound | 40 | 8 | — | — |
| phosphorus | Phosphazene compound | — | — | 15 | — |
| compound | | | | | |
| Peroxide | PERBUTYL P | 2 | 2 | 2 | 2 |

| Insoluble phosphorus compound:Soluble phosphorus compound | | | 17:83 | 83:17 | 57:43 | — |
|---|---|---|---|---|---|---|
| (ratio by mass) | | | | | | |
| Content of phosphorus atom (%) | | | 3.0 | 3.7 | 3.2 | 0 |
| Evaluation | Glass transition temperature Tg (° C.) | | 160 | 224 | 210 | 240 |
| | Interlayer adhesion strength (kN/m) | | 0.9 | 1.0 | 1.0 | 1.0 |
| | Dielectric constant | | 3.9 | 3.9 | 3.9 | 3.9 |
| | Dissipation factor | | 0.0015 | 0.001 | 0.0015 | 0.002 |
| | Flame retardancy (s) | | 52 | 42 | 28 | Combustion |
| | Chemical resistance | | OK | OK | OK | OK |
| | Heat resistance | 260° C. | OK | OK | OK | OK |
| | | 288° C. | NG | OK | OK | OK |

TABLE 4

| | | | | Examples | |
|---|---|---|---|---|---|
| | | | | 17 | 18 |
| Composition | Radically | Polybutadiene | | 100 | — |
| (part by mass) | polymerizable | Butadiene-styrene copolymer | | — | 100 |
| | compound | | | | |
| | Insoluble | Phosphine oxide compound 1 | melting point | 45 | 45 |
| | phosphorus | | 330° C. | | |
| | compound | Phosphinate compound | | — | — |
| | Peroxide | PERBUTYL P | | 2 | 2 |
| Insoluble phosphorus compound:Soluble phosphorus compound | | | | 100:0 | 100:0 |
| (ratio by mass) | | | | | |
| Content of phosphorus atom (%) | | | | 3.7 | 3.7 |
| Evaluation | Interlayer adhesion strength (kN/m) | | | 1.2 | 1.2 |
| | Dielectric constant | | | 3.8 | 3.8 |
| | Dissipation factor | | | 0.001 | 0.001 |
| | Flame retardancy (s) | | | 120 | 120 |
| | Chemical resistance | | | OK | OK |
| | Heat resistance | | 260° C. | OK | OK |
| | | | 288° C. | OK | OK |
| | | | | Comparative | |
| | | | | Examples | |
| | | | | 6 | 7 |
| Composition | Radically | Polybutadiene | | 100 | — |
| (part by mass) | polymerizable | Butadiene-styrene copolymer | | — | 100 |
| | compound | | | | |
| | Insoluble | Phosphine oxide compound 1 | melting point | — | — |
| | phosphorus | | 330° C. | | |

| | | | |
|---|---|---|---|
| compound | Phosphinate compound | 21 | 21 |
| Peroxide | PERBUTYL P | 2 | 2 |

| Insoluble phosphorus compound:Soluble phosphorus compound | | | 100:0 | 100:0 |
|---|---|---|---|---|
| (ratio by mass) | | | | |
| Content of phosphorus atom (%) | | | 3.9 | 3.9 |
| Evaluation | Interlayer adhesion strength (kN/m) | | 0.9 | 0.9 |
| | Dielectric constant | | 3.8 | 3.8 |
| | Dissipation factor | | 0.002 | 0.002 |
| | Flame retardancy (s) | | 120 | 120 |
| | Chemical resistance | | NG | NG |
| | Heat resistance | 260° C. | OK | OK |
| | | 288° C. | OK | OK |

As is clear from Tables 1 to 4, when the curable composition is used that contains the phosphine oxide compound as the insoluble phosphorus compound to be added together with the radically polymerizable compound (Examples 1 to 18), a cured product can be obtained that is excellent in flame retardancy while maintaining excellent dielectric properties. The cured product obtained with use of the curable composition according to Examples 1 to 18 is not only excellent in dielectric properties and flame retardancy, but also has a high glass transition temperature, is excellent in heat resistance and chemical resistance, and is high in interlayer adhesion strength.

In contrast, when the curable composition is used that contains no flame retardant (Comparative Example 1), the cured product is low in flame retardancy. When the curable composition is used that is a triphenylphosphine oxide having only one diphenylphosphine oxide group in a molecule (Comparative Example 2), the cured product is low in glass transition temperature and heat resistance. When the curable composition is used that contains, as the insoluble phosphorus compound, the phosphinate compound or the polyphosphate compound (Comparative Example 3 or 4), the cured product is low in chemical resistance and also in interlayer adhesion strength. This results are not sufficiently improved even when the soluble phosphorus compound is used in combination (Comparative Example 5).

As is clear from Table 4, even when polybutadiene or the butadiene-styrene copolymer is used as the radically polymerizable compound, use of the phosphine oxide compound as the insoluble phosphorus compound can give a cured product excellent in, for example, dielectric properties and flame retardancy. In this case, amorphousness is high and the glass transition temperature cannot be observed.

### INDUSTRIAL APPLICABILITY

A curable composition of the present invention is useful to obtain a prepreg, a composition-coated metal foil, a metal-clad laminate, and a wiring board that are excellent in heat resistance and flame retardancy.

### REFERENCE MARKS IN THE DRAWINGS

2 curable composition
3 composition layer
4 fibrous base material
10 prepreg
12 insulating layer
14 metal foil
15 composition-coated metal foil
16 wiring
20 metal-clad laminate
30 wiring board

1. A curable composition comprising:
a radically polymerizable compound having a carbon-carbon unsaturated double bond in a molecule; and
an insoluble phosphorus compound insoluble in the radically polymerizable compound,
the insoluble phosphorus compound including a phosphine oxide compound that has two or more diphenylphosphine oxide groups in a molecule.

2. The curable composition according to claim 1, wherein the phosphine oxide compound has a melting point of 280° C. or more.

3. The curable composition according to claim 1,
wherein the phosphine oxide compound has, in the molecule, a linking group that links the two or more diphenylphosphine oxide groups, and
the linking group includes at least one selected from the group consisting of a phenylene group, a xylylene group, a biphenylene group, a naphthylene group, a methylene group, and an ethylene group.

4. The curable composition according to claim 1, wherein the phosphine oxide compound is at least one selected from the group consisting of compounds represented by formulae (1-1) to (1-4): 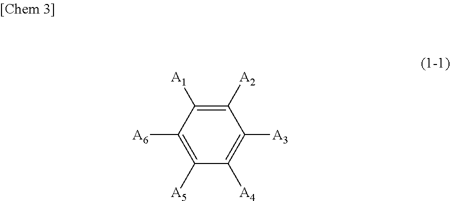
in the formula (1-1), two of A₁ to A₆ represent a diphenylphosphine oxide group, and remaining four of A₁ to A₆ represent a hydrogen atom, a methyl group, or a methoxy group; 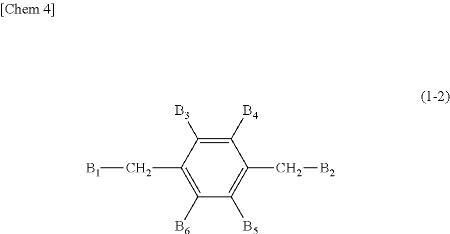
in the formula (1-2), B₁ and B₂ represent a diphenylphosphine oxide group, and B₃ to B₆ represent a hydrogen atom, a methyl group, or a methoxy group; 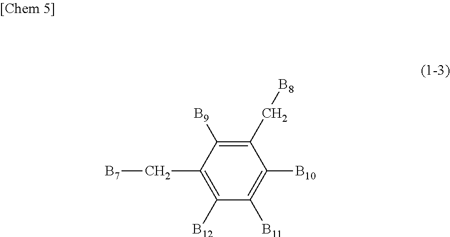
in the formula (1-3), B₇ and B₈ represent a diphenylphosphine oxide group, and B₉ to B₁₂ represent a hydrogen atom, a methyl group, or a methoxy group; 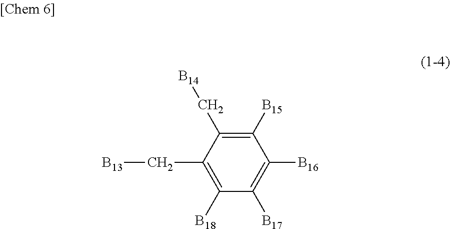
in the formula (1-4), B₁₃ and B₁₄ represent a diphenylphosphine oxide group, and B₁₅ to B₁₈ represent a hydrogen atom, a methyl group, or a methoxy group.

5. The curable composition according to claim 1, further comprising a soluble phosphorus compound soluble in the radically polymerizable compound.

6. The curable composition according to claim 5, wherein a content proportion by mass of the insoluble phosphorus compound to a total of the insoluble phosphorus compound and the soluble phosphorus compound ranges from 20% to 80%, inclusive.

7. The curable composition according to claim 5, wherein the soluble phosphorus compound is at least one selected from the group consisting of a phosphoric acid ester compound, a phosphazene compound, a phosphorous acid ester compound, and a phosphine compound.

8. The curable composition according to claim 1, wherein a content of a phosphorus atom ranges from 1.8% by mass to 5.2% by mass inclusive relative to a whole organic component.

9. The curable composition according to claim 1, wherein the radically polymerizable compound includes a modified polyphenylene ether compound terminally modified with a substituent having a carbon-carbon unsaturated double bond, and a crosslinking agent having two or more carbon-carbon unsaturated double bonds in a molecule.

10. The curable composition according to claim 9, wherein the modified polyphenylene ether compound has a weight average molecular weight ranging from 500 to 5000, inclusive, and an average of 1 to 5, inclusive, of the substituents in one molecule.

11. The curable composition according to claim 9, wherein the substituent at a terminal of the modified polyphenylene ether compound is a substituent having at least one selected from the group consisting of a vinylbenzyl group, an acrylate group, and a methacrylate group.

12. The curable composition according to claim 9, wherein a content proportion by mass of the modified polyphenylene ether compound to a total of the modified polyphenylene ether compound and the crosslinking agent ranges from 30% to 90%, inclusive.

13. The curable composition according to claim 9, wherein the crosslinking agent is at least one selected from the group consisting of a trialkenyl isocyanurate compound, a polyfunctional acrylate compound having two or more acrylic groups in a molecule, a polyfunctional methacrylate compound having two or more methacrylic groups in a molecule, and a polyfunctional vinyl compound having two or more vinyl groups in a molecule.

14. The curable composition according to claim 1, wherein the radically polymerizable compound is a polymer of a conjugated diene or a copolymer of a conjugated diene with a vinyl aromatic compound.

15. The curable composition according to claim 1, further comprising a peroxide.

16. A prepreg comprising the curable composition according to claim 1 or a semi-cured product of the curable composition, and a fibrous base material impregnated with the curable composition or the semi-cured product.

17. A composition-coated metal foil comprising a composition layer that includes the curable composition according to claim 1 or a semi-cured product of the curable composition, and a metal foil laminated on the composition layer.

18. A metal-clad laminate comprising an insulating layer that includes a cured product of the curable composition according to claim 1, and a metal foil laminated on the insulating layer.

19. A wiring board comprising an insulating layer that includes a cured product of the curable composition according to claim 1, and wiring laminated on the insulating layer.

20. The curable composition according to claim 5, wherein a content of a phosphorus atom ranges from 1.8% by mass to 5.2% by mass inclusive relative to a whole organic component.
